(19) United States
(12) Patent Application Publication
(10) Pub. No.: US 2018/0277563 A1
(43) Pub. Date: Sep. 27, 2018

(54) SEMICONDUCTOR MEMORY DEVICE AND METHOD FOR MANUFACTURING THE SAME

(71) Applicant: Toshiba Memory Corporation, Minato-ku (JP)

(72) Inventors: Kazuaki TSUNODA, Kuwana (JP); Hisakazu MATSUMORI, Yokkaichi (JP); Taichi IWASAKI, Yokkaichi (JP)

(73) Assignee: Toshiba Memory Corporaion, Minato-ku (JP)

(21) Appl. No.: 15/700,417

(22) Filed: Sep. 11, 2017

(30) Foreign Application Priority Data
Mar. 21, 2017 (JP) 2017-055132

(51) Int. Cl. H01L 27/11582; H01L 27/11565

(52) U.S. Cl. CPC H01L 27/11582; H01L 27/11565

(57) ABSTRACT

According to an embodiment, a semiconductor memory device includes a substrate, a stacked body, a first insulating film, and a first film. The stacked body is provided on the substrate. The stacked body includes a plurality of electrode films extending in a first direction along an upper surface of the substrate and stacked with spacing from each other. An end part of the stacked body has a stepped shape provided with a terrace for each of the electrode films. The first insulating film is provided on the end part of the stacked body. The first film is provided on the first insulating film, and extends in a direction tilted with respect to the first direction.

### CROSS-REFERENCE TO RELATED APPLICATIONS

This application is based upon and claims the benefit of priority from Japanese Patent Application No. 2017-055132, filed on Mar. 21, 2017; the entire contents of which are incorporated herein by reference.

### FIELD

Embodiments relate generally to a semiconductor memory device and a method for manufacturing the same.

### BACKGROUND

The semiconductor memory device having a three-dimensional structure has a structure having a memory array including a plurality of memory cells and a peripheral circuit integrated with each other. The memory cell array is provided with a stacked body having a plurality of electrode films stacked on one another, and the stacked body is provided with memory holes. An end part of the stacked body is processed to have a stepped shape, and each of the electrode films is led to the outside of the stacked body via a contact. In such an end part having the stepped shape, there is a problem that it becomes difficult to form the contact due to an increase in the number of electrode films stacked.

### BRIEF DESCRIPTION OF THE DRAWINGS

FIG. 1 is a cross-sectional view showing a semiconductor memory device according to a first embodiment;

FIG. 2 is a top view showing the semiconductor memory device according to the first embodiment;

FIG. 3 to FIG. 17 are cross-sectional views showing a method for manufacturing the semiconductor memory device according to the first embodiment;

FIG. 18 is a cross-sectional view showing a semiconductor memory device according to a second embodiment;

FIG. 19 to FIG. 32 are cross-sectional views showing a method for manufacturing the semiconductor memory device according to the second embodiment;

FIG. 33 is a cross-sectional view showing a semiconductor memory device according to a third embodiment;

FIG. 34 is a top view showing the semiconductor memory device according to the third embodiment;

FIG. 35 to FIG. 38 are cross-sectional views showing a method for manufacturing the semiconductor memory device according to the third embodiment;

FIG. 39 is a top view showing the method for manufacturing the semiconductor memory device according to the third embodiment;

FIG. 40 to FIG. 49 are cross-sectional views showing the method for manufacturing the semiconductor memory device according to the third embodiment;

FIG. 50 is a cross-sectional view showing a semiconductor memory device according to a fourth embodiment;

FIG. 51 to FIG. 64 are cross-sectional views showing a method for manufacturing the semiconductor memory device according to the fourth embodiment;

FIG. 65 is a cross-sectional view showing a semiconductor memory device according to a fifth embodiment;

FIG. 66A and FIG. 66B are top views showing parts of the semiconductor memory device according to the fifth embodiment; and

FIG. 67 to FIG. 72 are cross-sectional views showing a method for manufacturing the semiconductor memory device according to the fifth embodiment.

### DETAILED DESCRIPTION

According to an embodiment, a semiconductor memory device includes a substrate, a stacked body, a first insulating film, and a first film. The stacked body is provided on the substrate. The stacked body includes a plurality of electrode films extending in a first direction along an upper surface of the substrate and stacked with spacing from each other. An end part of the stacked body has a stepped shape provided with a terrace for each of the electrode films. The first insulating film is provided on the end part of the stacked body. The first film is provided on the first insulating film, and extends in a direction tilted with respect to the first direction.

Embodiments of the invention will now be described with reference to the drawings.

The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

In the drawings and the specification of the application, components similar to those described thereinabove are marked with like reference numerals, and a detailed description is omitted as appropriate.

### First Embodiment

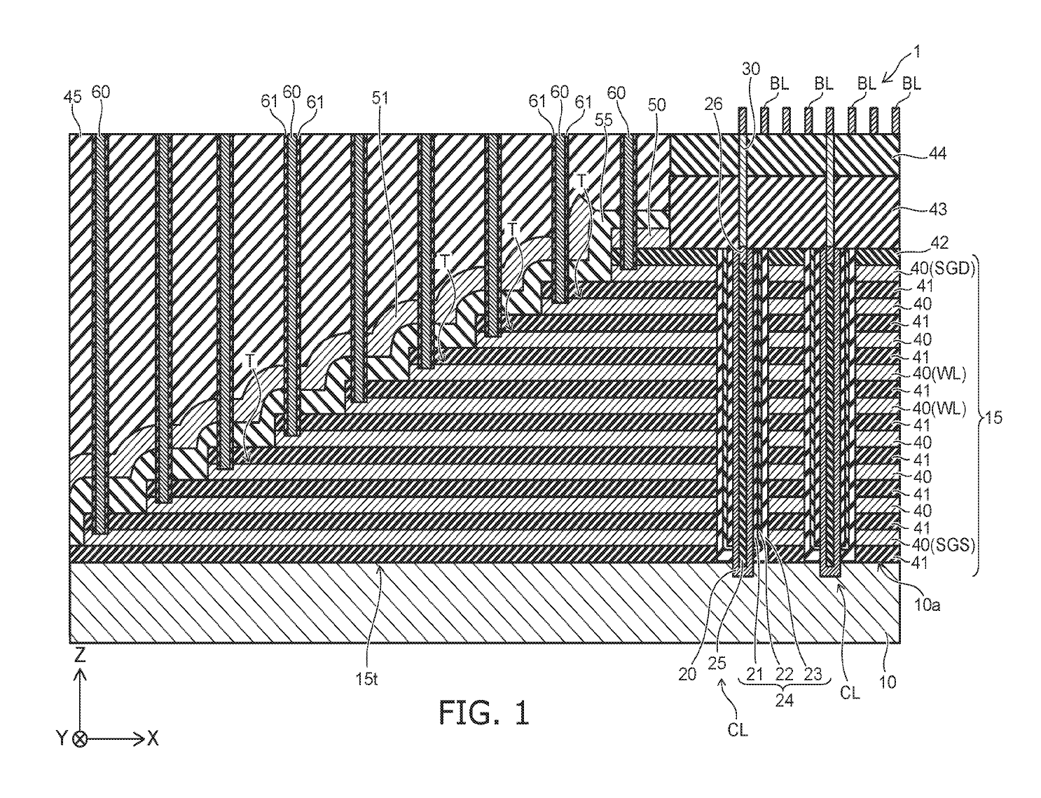

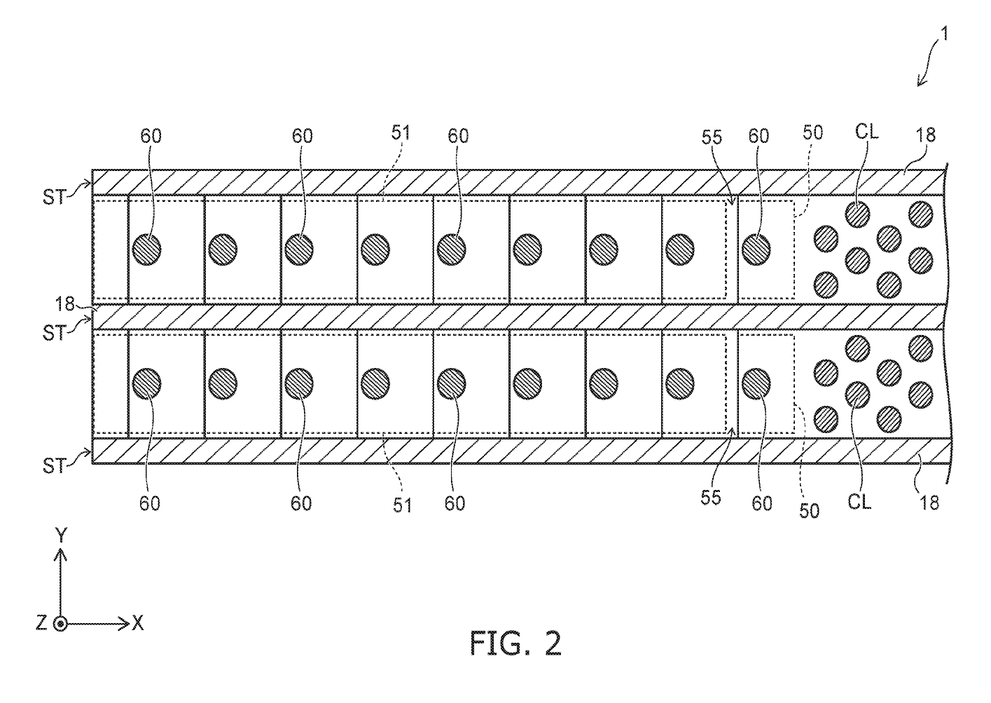

FIG. 1 is a cross-sectional view showing a semiconductor memory device 1. FIG. 2 is a top view of the semiconductor memory device 1, and shows an upper surface of the area shown in FIG. 1.

As shown in FIG. 1, the semiconductor memory device 1 is provided with a substrate 10. The substrate 10 is a semiconductor substrate, and includes silicon (Si) such as single-crystal silicon.

It should be noted that in the specification, two directions parallel to the upper surface 10a of the substrate 10, and perpendicular to each other are defined as an X-direction and a Y-direction. A direction perpendicular to both of the X-direction and the Y-direction is defined as a Z-direction.

The semiconductor memory device 1 is provided with a stacked body 15 and a plurality of columnar sections. The stacked body 15 includes a source-side selection gate SGS, a drain-side selection gate SGD, a plurality of word lines WL, and a plurality of insulating films 41. The stacking direction of the stacked body 15 corresponds to the Z-direction.

For example, the source-side selection gate SGS is provided on the substrate 10 via the insulating film 41, and the drain-side selection gate SGD is provided to the uppermost layer of the stacked body 15. The plurality of word lines WL is provided between the source-side selection gate SGS and the drain-side selection gate SGD. The source-side selection gate SGS, the word lines WL, and the drain-side selection gate SGD are each an electrode film 40. The electrode films 40 each include a conductive material. The electrode films 40 each include metal such as tungsten (W) or molybdenum (Mo). The electrode films 40 each include, for example, polysilicon.

The insulating films 41 are each provided between the electrode films 40. The insulating films 41 each include, for example, silicon oxide (SiO). On the stacked body 15, there are provided an insulating film 42, an insulating film 43 and an insulating film 44 in sequence in the Z-direction. The insulating film 42, the insulating film 43 and the insulating film 44 each include, for example, silicon oxide.

The plurality of columnar sections CL is provided in the stacked body 15. The columnar sections CL extend through the stacked body 15 and the insulating film 42 in the Z-direction. The columnar sections CL each include a core part 25, a channel 20 and a memory film 24.

The core part 25 includes, for example, silicon oxide. The shape of the core part 25 is, for example, a cylindrical shape. The upper end of the core part 25 is provided with a contact plug 26 formed of silicon or the like. The contact plug 26 is surrounded by the channel 20, and the upper end of the contact plug 26 is connected to a contact 30.

The channel 20 is provided on the periphery of the core part 25. The channel 20 is a semiconductor part, and includes, for example, silicon. The channel 20 includes, for example, polysilicon obtained by crystallizing amorphous silicon. The shape of the channel 20 is, for example, a bottomed cylindrical shape.

The memory film 24 is provided on the periphery of the channel 20. The memory film 24 has a tunnel insulating film 21, a charge storage film 22, and a block insulating film 23. The tunnel insulating film 21 is provided on the periphery of the channel 20. The tunnel insulating film 21 includes, for example, silicon oxide.

The charge storage film 22 is provided on the periphery of the tunnel insulating film 21. The charge storage film 22 includes, for example, silicon nitride (SiN). In the crossing part between the channel 20 and each of the word lines WL, there is formed a memory cell including the charge storage film 22. A number of memory cells are arranged along the X-direction, the Y-direction, and the Z-direction in a three-dimensional matrix, and data can be stored in each of the memory cells.

The block insulating film 23 is provided on the periphery of the charge storage film 22. For example, the block insulating film 23 is a silicon oxide film including silicon oxide, an aluminum oxide film including aluminum oxide (AlO), or a stacked film of these films.

Above the columnar section CL, there is provided a plurality of bit lines BL extending in the Y-direction. The upper end of each of the columnar sections CL is connected to one of the bit lines BL via the contact 30. The contact 30 extends through the insulating film 43 and the insulating film 44, and includes a conductive material such as metal.

As shown in FIG. 2, the semiconductor memory device 1 is provided with a plurality of slits ST. The slits ST extend through the stacked body 15, the insulating film 42 and the insulating film 43 in the Z-direction. Further, the slits ST extend in the X-direction from the center toward the end part 15t of the stacked body 15. As shown in FIG. 1 and FIG. 2, the shape of the end part 15t of the stacked body 15 is the stepped shape with terraces T provided to the respective electrode films 40. Here, the stepped structure denotes a structure having horizontal surfaces (the terraces) and vertical surfaces (steps) disposed alternately.

The slits ST separate the stacked body 15 into a plurality of regions in the Y-direction. The regions separated by the slits ST are each called a “block.” The columnar sections CL are located in each of the blocks, and the channels 20 of the columnar sections CL each selected singly from one of the blocks are electrically connected to one bit line BL. Further, by the slits ST separating the stacked body 15, a plurality of end parts 15t having the stepped shape is disposed along the Y-direction.

An interconnection part 18 is provided in the slit ST. The interconnection part 18 extends along the Z-direction and the X-direction. The interconnection part 18 includes a conductive material such as metal. The lower end of the interconnection part 18 has contact with the substrate 10. The upper end of the interconnection part 18 is connected to a source line (not shown) extending in the Y-direction via the contact. In other words, the interconnection part 18 constitutes a part of the source line.

Further, in the slit ST, a sidewall (not shown) having an insulating property is provided on the side surface of the interconnection part 18 to electrically isolate between the interconnection part 18 and the electrode films 40 of the stacked body 15.

The semiconductor memory device 1 is provided with a conductive film 50, an insulating film 55, a conductive film 51, and a plurality of contacts 60. The conductive film 50, the conductive film 51, the insulating film 55 and the contacts 60 are provided on the end part 15t of the stacked body 15.

The conductive film 50 is provided on the insulating film 42 in the end part 15t of the stacked body 15. As indicated by the dotted lines in FIG. 2, the conductive film 50 is located between the slits ST. Further, when viewed from the Z-direction, at least a part of the conductive film 50 overlaps the contact 60. Although the shape of the conductive film 50 is a rectangular shape when viewed from the Z-direction in the example shown in FIG. 2, the shape of the conductive film 50 is not limited to this example. The conductive film 50 includes the same conductive material as the conductive material which the electrode films 40 are formed of, and includes metal such as tungsten or molybdenum. The conductive film 50 includes, for example, polysilicon.

The insulating film 55 covers the end part 15t of the stacked body 15 so that a part of the insulating film 55 is located on the conductive film 50. As shown in FIG. 2, the insulating film 55 is located between the slits ST. The insulating film 55 includes, for example, silicon oxide.

The conductive film 51 is provided on a part of the insulating film 55. Specifically, the conductive film 51 is not provided on the insulating film 55 located on the conductive film 50. Thus, as indicated by the dotted lines in FIG. 2, the conductive film 51 is not overlapped with the conductive film 50 when viewed from the Z-direction. Further, the conductive film 51 is located between the slits ST. When viewed from the Z-direction, at least a part of the conductive film 51 overlaps the contacts 60.

Although the shape of the conductive film 51 is a rectangular shape when viewed from the Z-direction in the example shown in FIG. 2, the shape of the conductive film 51 is not limited to this example. The conductive film 51 includes the same conductive material as the conductive material which the electrode films 40 and the conductive film 50 are formed of, and includes metal such as tungsten or molybdenum. The conductive film 51 includes, for example, polysilicon.

It should be noted that in the specification, the conductive film 50 and the conductive film 51 are called a conductive part in some cases.

On the insulating film 55 and the conductive film 51, there is provided an insulating film 45. The insulating film 45 includes, for example, silicon oxide. The insulating film 45 includes, for example, TEOS (tetraethoxysilane).

The contacts 60 are respectively located on the terraces T of the electrode films 40, and extend in the Z-direction in the end part 15t of the stacked body 15. The contact 60 located on the terrace T of the electrode film 40 (the drain-side selection gate SGD) as the uppermost layer penetrates the insulating film 45, the insulating film 55, the conductive film 50 and the insulating film 42. The contacts 60 located on the terraces T of the electrode films 40 (the source-side selection gate SGS and the word lines WL) except the electrode film 40 as the uppermost layer each penetrate the insulating film 45, the conductive film 51, the insulating film 55, and the insulating film 41.

In each of the contacts 60, the lower end is connected to the electrode film 40, and the upper end is connected to an upper-layer interconnection (not shown) extending in the X-direction. Each of the electrode films 40 is led, and is connected to a peripheral circuit via the contact 60 and the upper-layer interconnection. The contacts 60 each include a conductive material such as tungsten. The shape of each of the contacts 60 is, for example, a cylindrical shape or a polygonal column shape. It should be noted that the number of the contacts 60 and the positions of the contacts 60 with respect to the terraces T are arbitrarily set.

On the periphery of each of the contacts 60, there is provided a spacer 61 having an insulating property. The spacer 61 includes, for example, silicon oxide. The spacer 61 is an insulating part, and electrically isolates the contact 60 and the conductive part from each other.

Then, a method of manufacturing the semiconductor memory device according to the embodiment will be described.

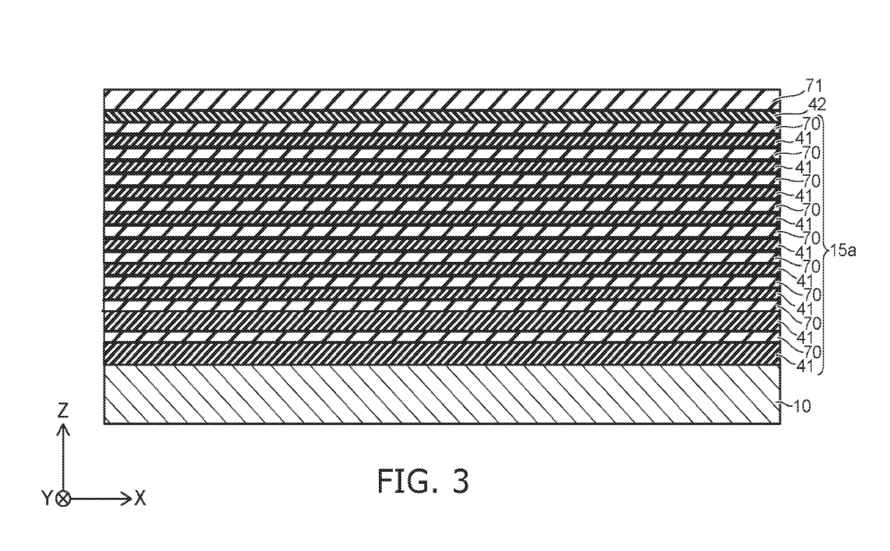

FIG. 3 through FIG. 17 are cross-sectional views showing the method of manufacturing the semiconductor memory device FIG. 3 through FIG. 17 show the area corresponding to the end part 15t of the stacked body 15 in FIG. 1.

Firstly, as shown in FIG. 3, the insulating films 41 and sacrificial films 70 are alternately stacked on one another along the Z-direction using, for example, a CVD (Chemical Vapor Deposition) method to form the stacked body 15a on the substrate 10 including silicon. The sacrificial films 70 are formed of a material capable of providing a sufficient etching selectivity with the insulating films 41, and are formed of, for example, silicon nitride.

Subsequently, the insulating film 42 is formed on the stacked body 15a by, for example, the CVD method. Subsequently, a sacrificial film 71 is selectively formed in the end part 15t of the stacked body 15a and on the insulating film 42 using a mask. The sacrificial film 71 is formed of, for example, silicon oxide. It should be noted that in the region of the stacked body 15a except the end part 15t, the memory holes are formed, and then the memory film 24, the channel 20 and the core part 25 are formed in sequence in each of the memory holes. Thus, the columnar sections CL are formed.

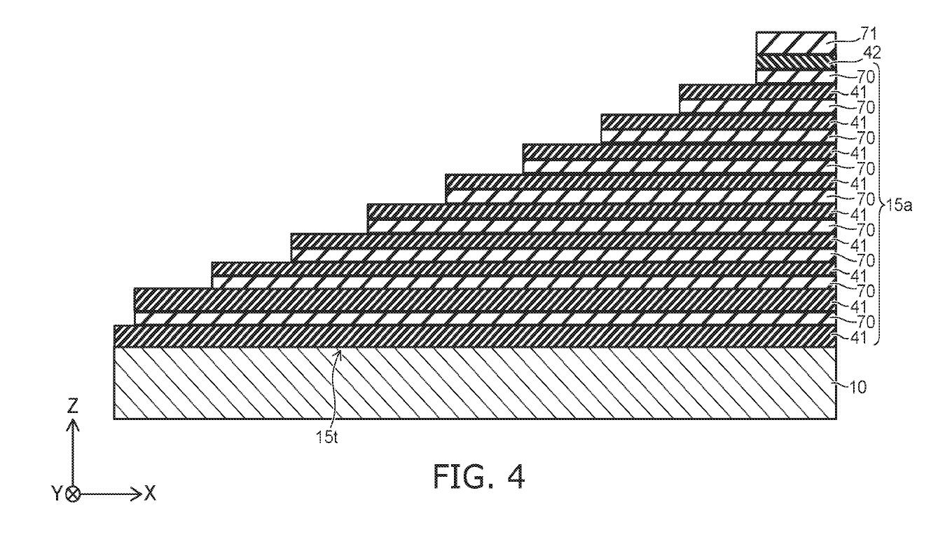

Then, as shown in FIG. 4, the end part 15t of the stacked body 15a is processed to have the stepped shape by, for example, alternately repeating an isotropic etching process such as RIE (Reactive Ion Etching) using a resist film as a mask, and a slimming treatment such as ashing for reducing the volume of the resist film. Such an end part 15t having the stepped shape is formed by repeating the process of etching the resist film on the stacked body 15a in order to control the etching amount of the stacked body 15a, and then etching the stacked body 15a downward. Thus, the insulating film 42 partially removed, and the sacrificial film 71 are formed in sequence on the end part 15t having the stepped shape.

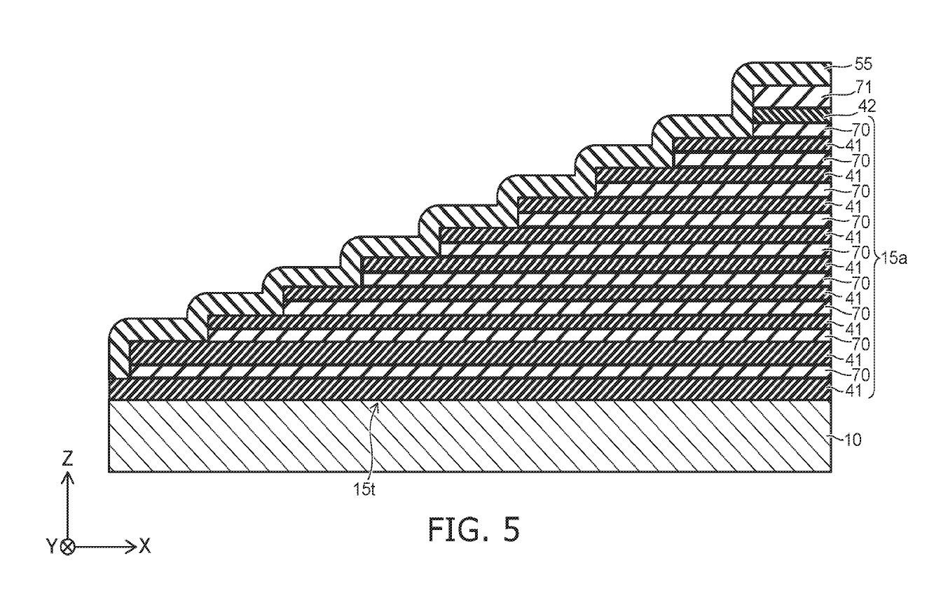

Then, as shown in FIG. 5, the insulating film 55 is formed so as to cover the end part 15t of the stacked body 15a using, for example, the CVD method. A part of the insulating film 55 is formed on the sacrificial film 71.

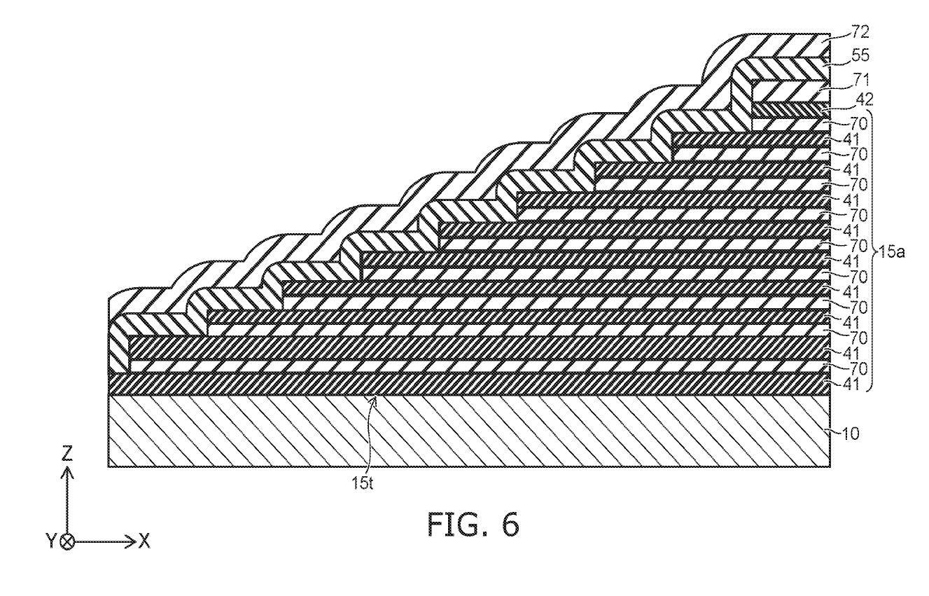

Then, as shown in FIG. 6, a sacrificial film 72 is formed on the insulating film 55. The sacrificial film 72 is formed of, for example, silicon nitride.

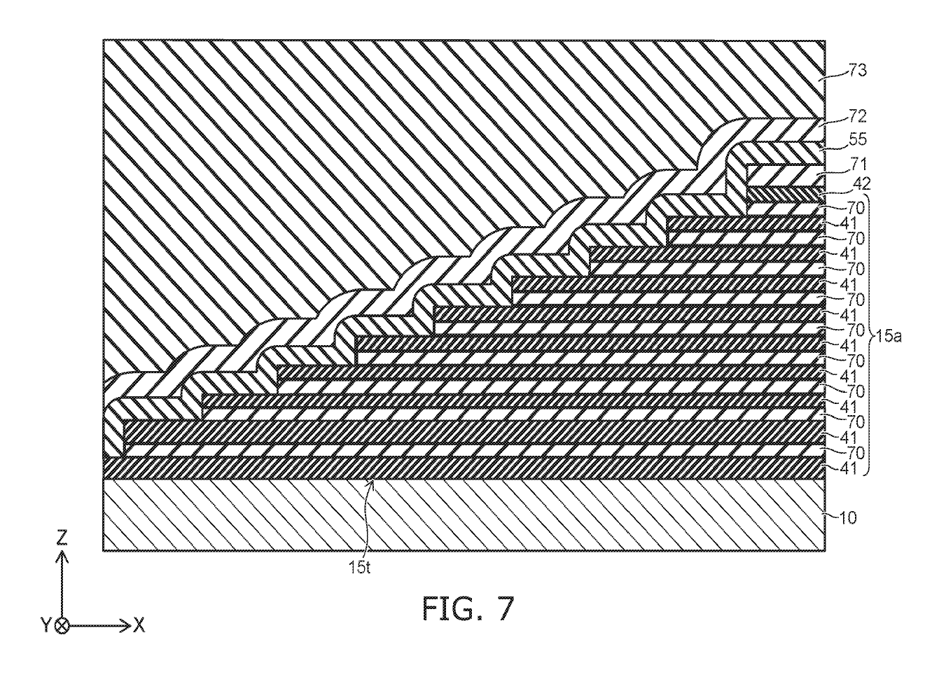

Then, as shown in FIG. 7, an insulating film 73 is formed on the sacrificial film 72 using, for example, the CVD method. The insulating film 73 is formed of, for example, TEOS.

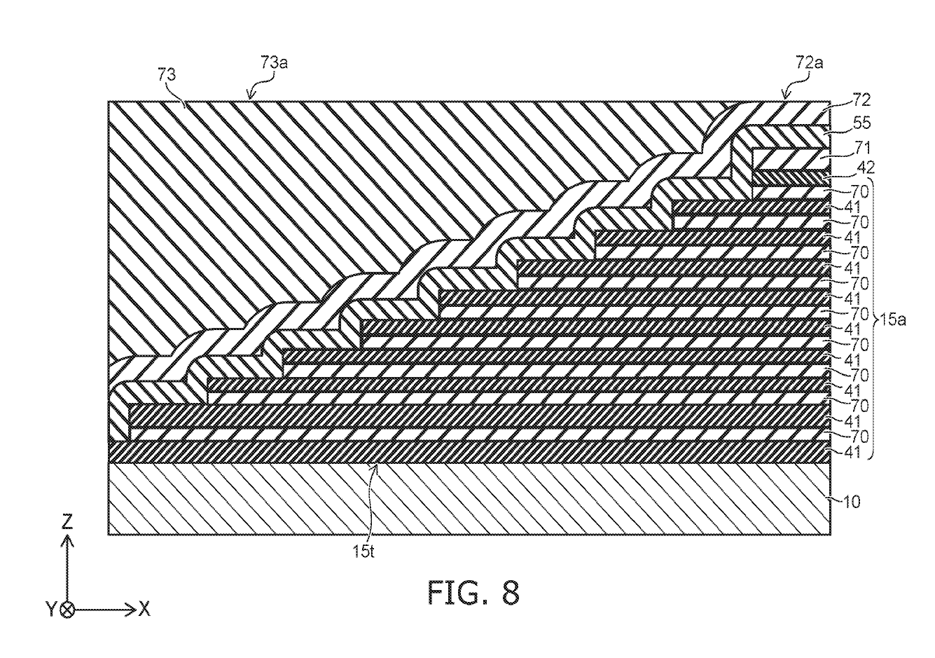

Then, as shown in FIG. 8, a part of the insulating film 73 is removed and then planarization is performed using a CMP (Chemical Mechanical Polishing) method. Due to the planarization process, the upper surface 72a of the sacrificial film 72 located above the sacrificial film 71 is located on roughly the same plane as the upper surface 73a of the insulating film 73.

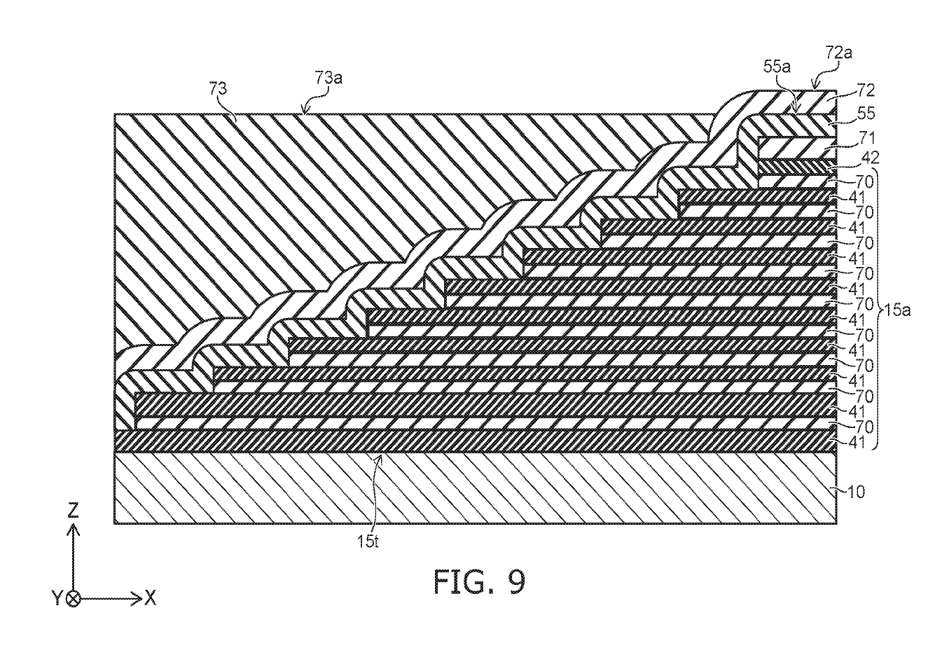

Then, as shown in FIG. 9, the insulating film 73 is etched back using an etching process. Thus, the upper surface 55a of the insulating film 55 on the sacrificial film 71 is located on roughly the same plane as the upper surface 73a of the insulating film 73.

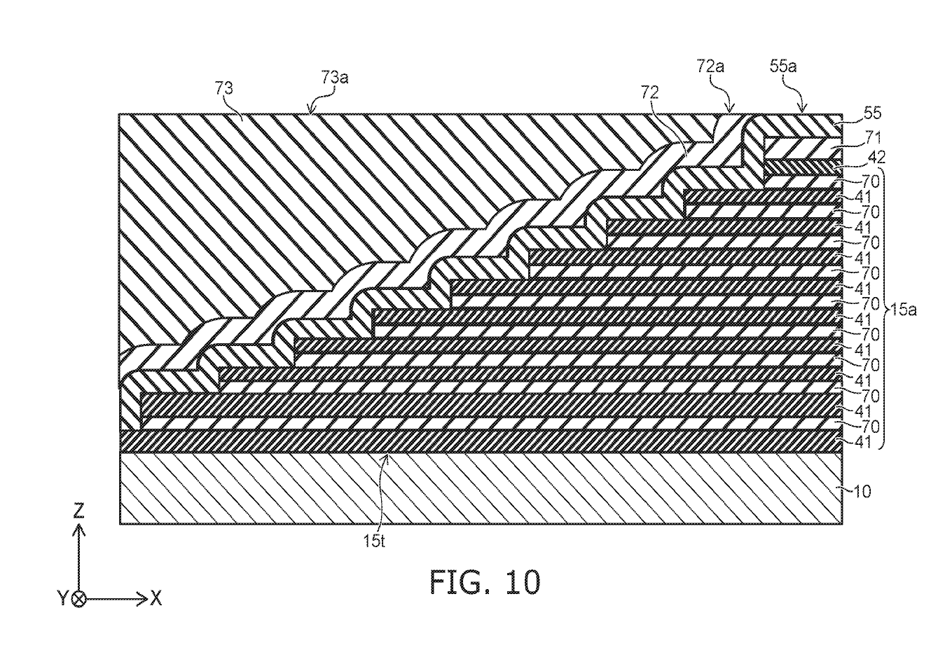

Then, as shown in FIG. 10, a part of the sacrifice film 72 is removed using an etching process such as RIE. Thus, the upper surface 72a of the sacrificial film 72 is located on roughly the same plane as the upper surface 55a of the insulating film 55, and the upper surface 73a of the insulating film 73.

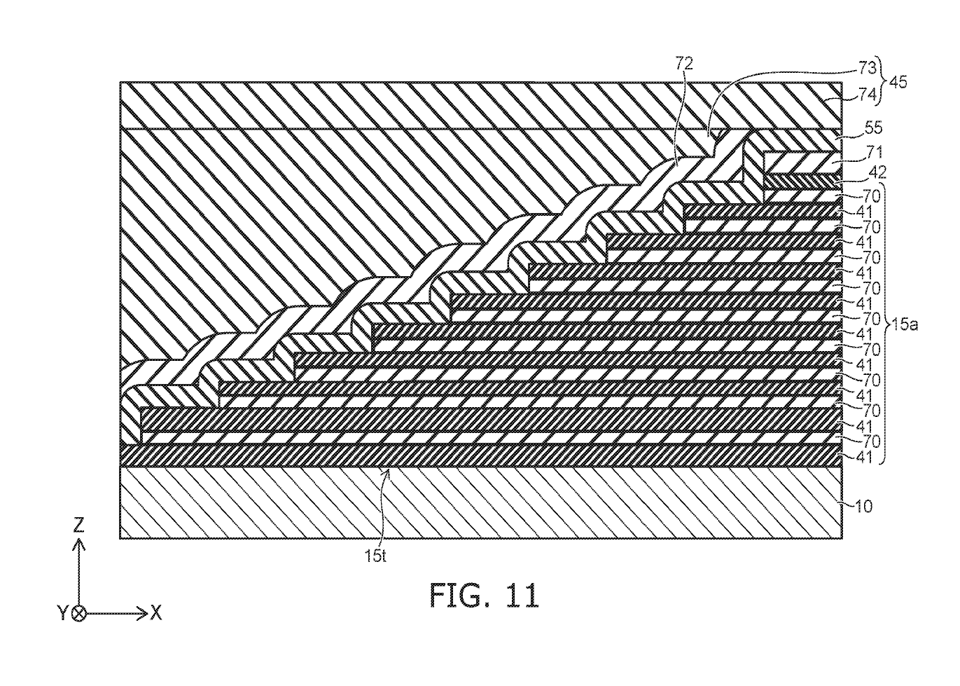

Then, as shown in FIG. 11, an insulating film 74 is formed on the insulating film 55, the sacrificial film 72 and the insulating film 73 using, for example, the CVD method. The insulating film 74 is formed of, for example, TEOS. Thus, the insulating film 45 having the insulating film 73 and the insulating film 74 is formed.

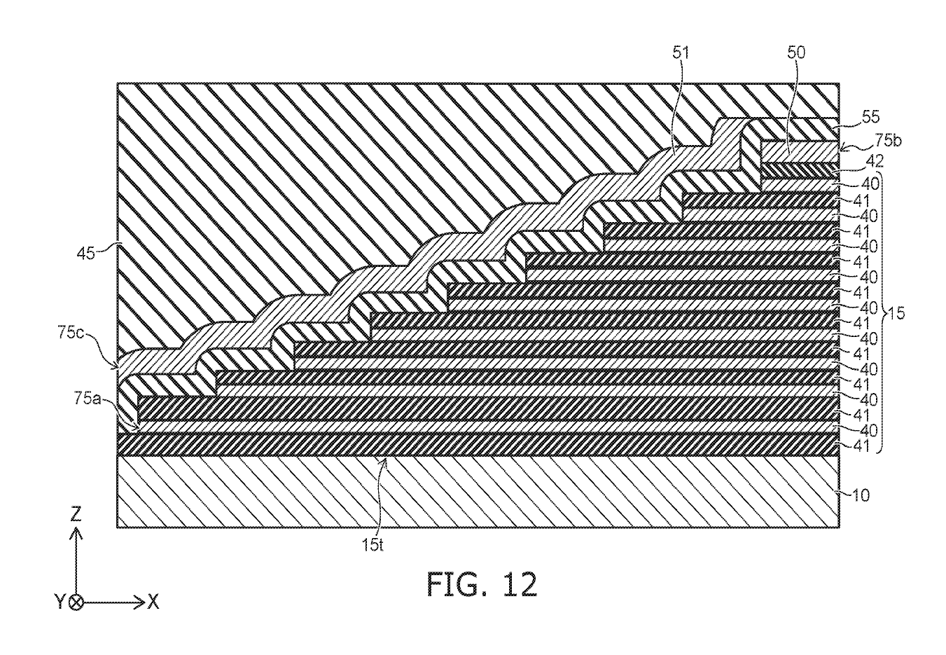

Then, as shown in FIG. 12, a plurality of slits ST (see FIG. 2) extending in the X-direction and the Z-direction is provided to the stacked body 15a using an etching process such as RIE. The stacked body 15a is segmentalized by the slits ST into a plurality of stacked bodies each extending in the X-direction. Further, the insulating films 45, 55 are each segmentalized by the slits ST, and at the same time, the sacrificial films 71, 72 are each segmentalized by the slits ST.

Subsequently, wet-etching is performed via the slits ST to thereby remove the sacrificial films 70, 71, 72. In the case in which the sacrificial films 70, 71, 72 are formed of the silicon nitride, phosphoric acid is used as the etchant of the wet-etching, and the etching process is performed using hot phosphoric acid. By removing the sacrificial films 70, 71, 72 via the slits ST, hollows 75a, 75b, 75c are formed. Subsequently, metal such as tungsten is deposited via the slits ST to fill in the hollows 75a, 75b, 75c.

By filling in the hollows 75a, 75b, 75c, the electrode films 40, the conductive films 50, and the conductive films 51 are formed, respectively. The sacrificial films 70 are replaced with the electrode films 40, and thus, the stacked body 15 is formed between the slits ST. In the end part 15t of the stacked body 15, the terraces T are provided to the respective electrode films 40. Subsequently, the interconnection part 18 is formed in each of the slits ST.

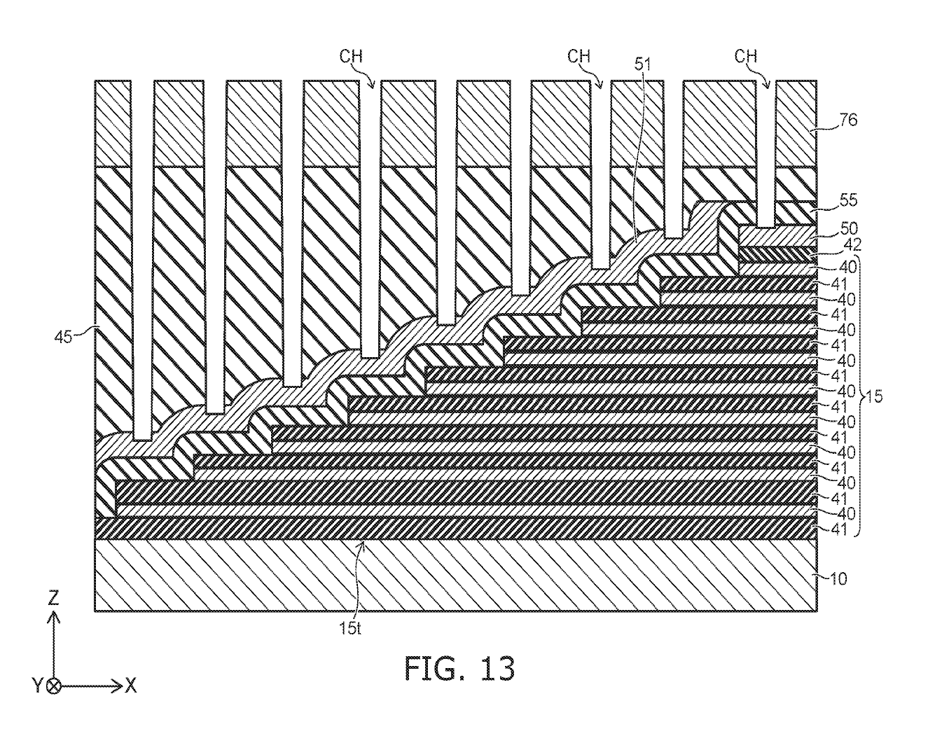

Then, as shown in FIG. 13, an insulating film 76 is formed on the insulating film 45 using, for example, the CVD method. The insulating film 76 is formed of, for example, amorphous carbon.

Subsequently, the contact holes CH are formed in the insulating films 45, 55, 76 using an etching process such as RIE. The contact hole CH provided to the uppermost layer of the stacked body 15 penetrates the insulating films 76, 45, 55 and reaches the conductive film 50. The contact holes CH provided to other layers than the uppermost layer of the stacked body 15 penetrate the insulating films 76, 45 and reach the conductive film 51.

It is possible to stop etching without penetrating the conductive films 50, 51 by the insulating film 76 thickly formed on the insulating film 45, and the etching selectivity between the insulating film 45 (e.g., a TEOS film) and the conductive films 50, 51 (e.g., metal films made of tungsten). In other words, the conductive films 50, 51 function as films for stopping etching.

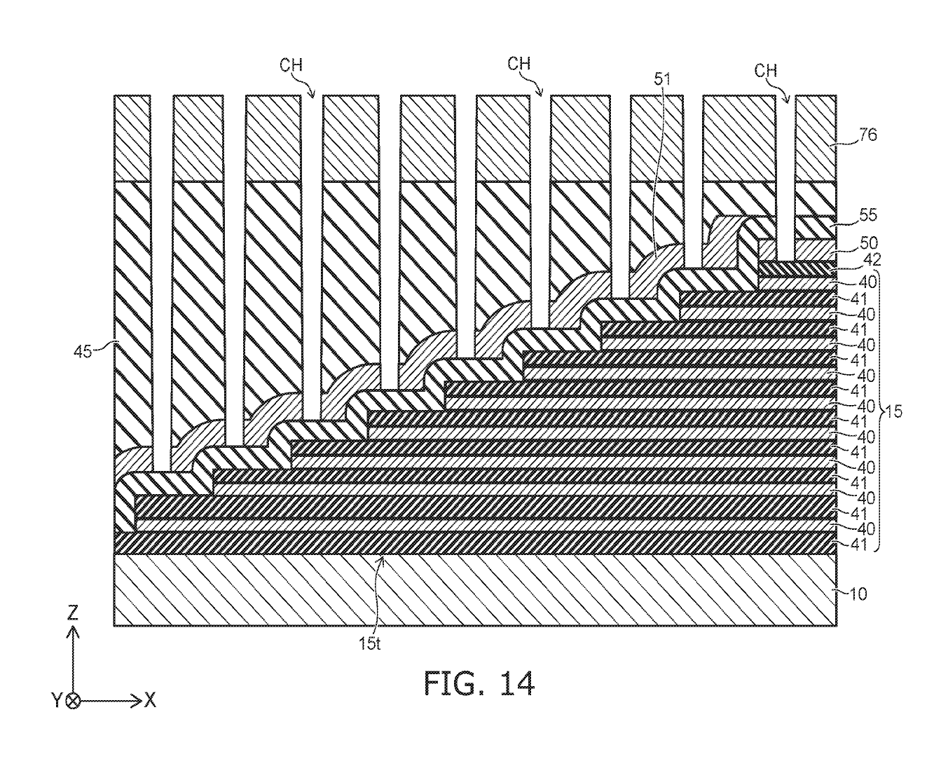

Then, as shown in FIG. 14, the conductive films 50, 51 located immediately below the contact holes CH are removed using an etching process such as RIE. Thus, the contact hole CH provided to the uppermost layer of the stacked body 15 penetrates the conductive film 50 to reach the insulating film 42. The contact holes CH provided to other layers than the uppermost layer of the stacked body 15 penetrate the conductive film 51 and reach the insulating film 55. The etching conditions between the conductive films 50, 51 and the insulating films 42, 55 are set so as not to penetrate the insulating films 42, 55. It should be noted that a part of the insulating film 76 is removed together with the removal of the conductive films 50, 51.

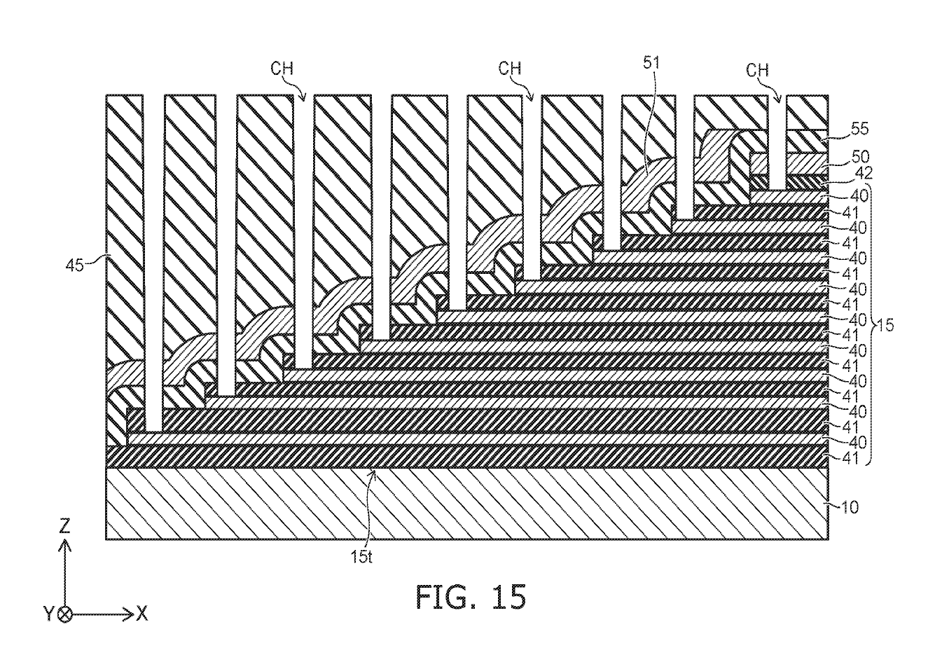

Then, as shown in FIG. 15, the insulating films 55, 41, 42 located immediately below the contact holes CH are removed using an etching process such as RIE. Thus, the contact hole CH provided to the uppermost layer of the stacked body 15 penetrates the insulating film 42 to reach the electrode film 40 (the drain-side selection gate SGD). The contact holes CH provided to other layers than the uppermost layer of the stacked body 15 penetrate the insulating films 55, 41 to reach the electrode films 40 (the source-side selection gate SGS or the word lines WL). The etching conditions between the insulating films 41, 42, 55 and the electrode films 40 are set so as not to penetrate the electrode films 40. It should be noted that a part of the insulating film 76 is removed together with the removal of the insulating films 42, 41.

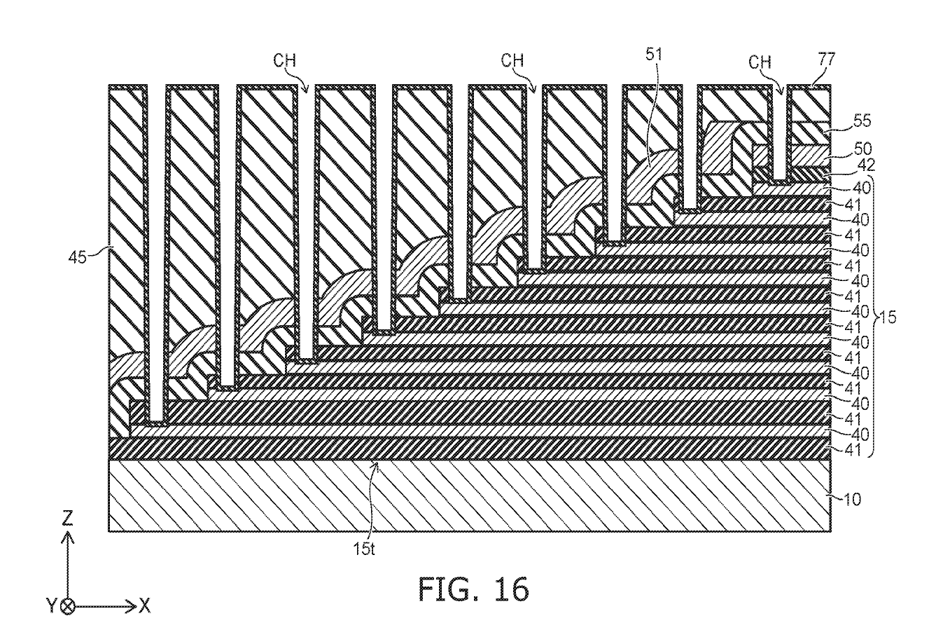

Then, as shown in FIG. 16, an insulating film 77 is formed on the entire surface using, for example, an ALD (Atomic Layer Deposition) method. The insulating film 77 is formed of, for example, silicon oxide. The insulating film 77 is formed in a film formation condition good in coverage, and is formed on the insulating film 45, and the inside wall surface and the bottom surface of each of the contact holes CH.

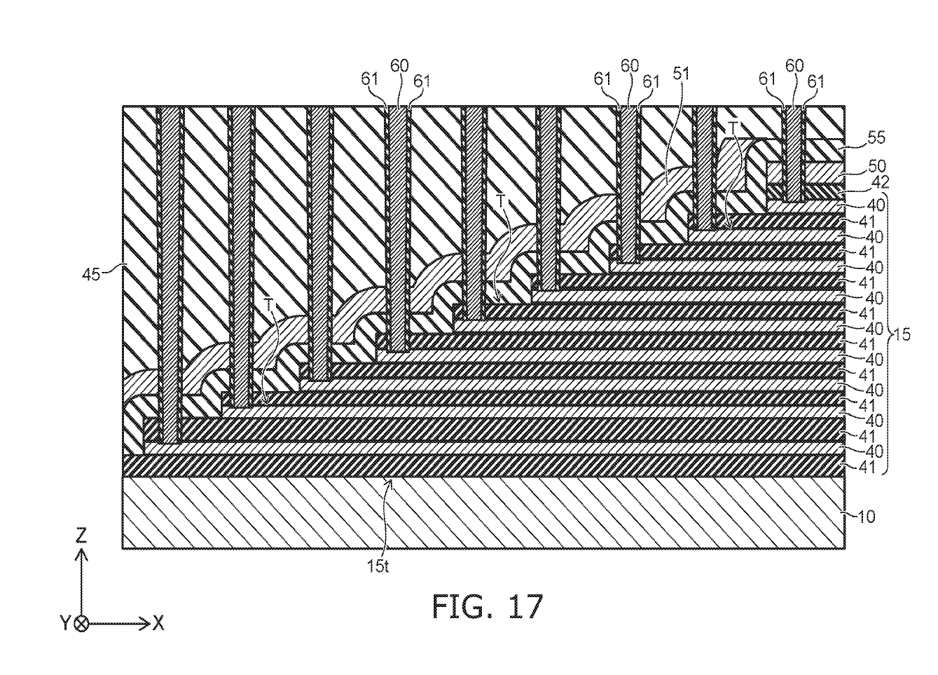

Then, as shown in FIG. 17, the upper surface of the insulating film 45 is removed to thereby remove the insulating film 77 on the insulating film 45 and remove the insulating film 77 on the bottom surface of each of the contact holes CH using an etching process such as RIE. By removing a part of the insulating film 77, the spacer 61 is formed. Subsequently, metal such as tungsten is deposited in each of the contact holes CH to form the contact 60. The contacts 60 are respectively located on the terraces T of the electrode films 40, and extend in the Z-direction in the end part 15t of the stacked body 15.

The semiconductor memory device 1 is manufactured in such a manner as described above.

It should be noted that it is also possible to form the conductive film 50 in the end part 15t of the stacked body 15a instead of forming the sacrificial film 71 in the process shown in FIG. 3, and form the conductive film 51 on the insulating film 55 instead of forming the sacrificial film 72 in the process shown in FIG. 6. In the case of directly forming the conductive layers 50, 51 as described above, the process of depositing the metal to fill in the hollows 75b, 75c is not performed after removing the sacrificial films 71, 72 by etching in the process shown in FIG. 12. Thus, it is possible to simplify the process in the method of manufacturing the semiconductor memory device 1.

Then, advantages of the embodiment will be described.

In the semiconductor memory device having the three-dimensional structure, in the case of providing the contacts to the end part of the stacked body, there is a possibility that as the number of the electrode films stacked increases, the aspect ratio of each of the contact holes rises, and at the same time, the thickness of each of the electrode films gets thinner. Further, the shape of the end part of the stacked body is a stepped shape, and it results that the height of the contact hole differs between the upper-layer electrode film and the lower-layer electrode film. Thus, in the case of forming the plurality of contact holes in a lump from the upper-layer electrode film to the lower-layer electrode film, it becomes difficult to ensure the etching selectivity between the electrode films and the insulating films on the respective electrode films as the number of electrode layers stacked increases. If the etching selectivity between the electrode films and the insulating films is low, short circuit between the electrode films is apt to occur due to the fact that the contact hole formed on the terrace of the electrode film penetrates the electrode film and the insulating film immediately below the electrode film.

In the embodiment, the semiconductor memory device 1 has the conductive film 50 and the insulating film 55 provided on the end part 15t having the stepped shape of the stacked body 15, and the conductive film 51 provided on the insulating film 55. The conductive films 50, 51 disposed in such a manner function as films for stopping etching as shown in FIG. 13. Thus, as shown in FIG. 14 and FIG. 15, it is possible to make the insulating films (the insulating films 41, 42, 55), which are etched once again after the etching is once stopped by the conductive films 50, 51, roughly equal in thickness to each other from the upper-layer electrode film 40 to the lower-layer electrode film 40. Then, by etching these insulating films in a step-by-step manner from the upper-layer electrode film 40 to the lower-layer electrode film 40, it is possible to prevent the contact holes CH from penetrating the electrode films 40 and the insulating films 41 immediately below the respective electrode films 40. Therefore, it is possible to prevent the short circuit between the electrode films 40, which occurs due to the penetration by the contact hole CH.

### Second Embodiment

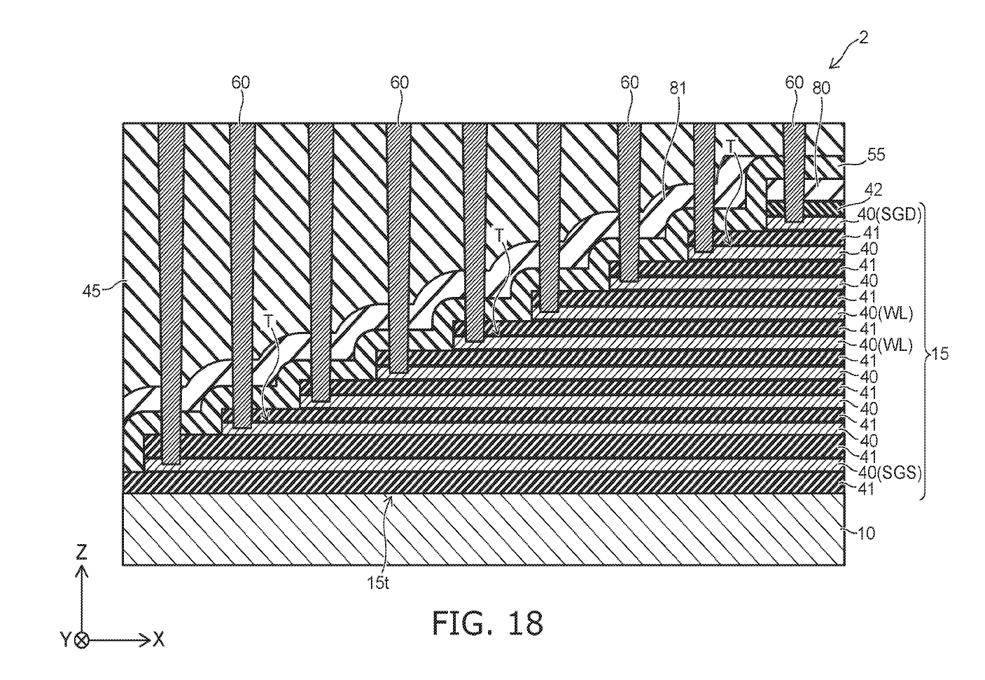

FIG. 18 is a cross-sectional view showing a semiconductor memory device 2. The area shown in FIG. 18 corresponds to the area showing the end part 15t of the stacked body 15 in FIG. 1.

As shown in FIG. 18, the semiconductor memory device 2 according to the embodiment is different in the point that insulating films 80, 81 are provided instead of the conductive part (the conductive films 50, 51) compared to the semiconductor memory device 1 according to the first embodiment.

The semiconductor memory device 2 is provided with the insulating film 80, the insulating film 55, the insulating film 81, and the plurality of contacts 60. The insulating film 55, the insulating film 80, the insulating film 81 and the contacts 60 are provided on the end part 15t of the stacked body 15. The insulating film 80 is provided on the insulating film 42 in the end part 15t of the stacked body 15. The insulating film 80 is located between the slits ST. Further, when viewed from the Z-direction, at least a part of the insulating film 80 overlaps the contact 60. The insulating film 80 includes at least one of, for example, aluminum oxide, hafnium oxide (HfO), and titanium oxide (TiO).

The insulating film 55 covers the end part 15t of the stacked body 15 so that a part of the insulating film 55 is located on the insulating film 80.

The insulating film 81 is provided on a part of the insulating film 55. Specifically, the insulating film 81 is not provided on the insulating film 55 located on the insulating film 80. Thus, the insulating film 81 does not overlap the insulating film 80 viewed from the Z-direction. Further, the insulating film 81 is located between the slits ST. When viewed from the Z-direction, at least a part of the insulating film 81 overlaps the contacts 60. The insulating film 81 includes the same insulating material as the insulating material which the insulating film 80 is formed of, and includes at least one of, for example, aluminum oxide, hafnium oxide (HfO), and titanium oxide (TiO).

It should be noted that in the specification, the insulating film 80 and the insulating film 81 are called an insulating part in some cases.

The contacts 60 are respectively located on the terraces T of the electrode films 40, and extend in the Z-direction in the end part 15t of the stacked body 15. The contact 60 located on the terrace T of the electrode film 40 (the drain-side selection gate SGD) as the uppermost layer penetrates the insulating films 45, 55, 80, 42. The contacts 60 located on the terraces T of the electrode films 40 (the source-side selection gate SGS and the word lines WL) except the electrode film 40 as the uppermost layer each penetrate the insulating films 45, 81, 55, 42.

It should be noted that unlike the first embodiment, the spacer 61 is not provided on the periphery of the contact 60 in the embodiment.

Then, a method of manufacturing the semiconductor memory device according to the embodiment will be described.

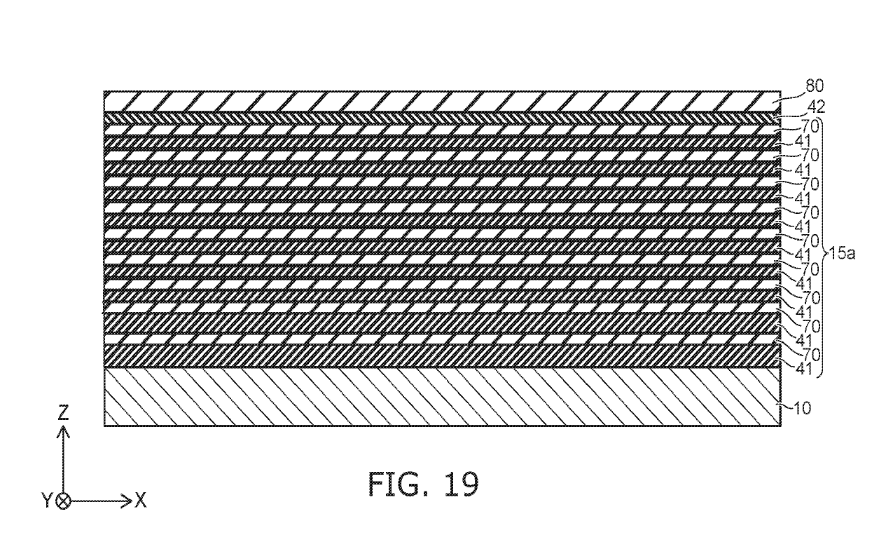

FIG. 19 through FIG. 32 are cross-sectional views showing the method of manufacturing the semiconductor memory device 2.

FIG. 19 through FIG. 32 each show the area corresponding to FIG. 18.

Firstly, as shown in FIG. 19, the insulating films 41 and the sacrificial films 70 are alternately stacked on one another along the Z-direction to form the stacked body 15a on the substrate 10. Subsequently, the insulating film 42 is formed on the stacked body 15a. Subsequently, the insulating film 80 is selectively formed in the end part 15t of the stacked body 15a and on the insulating film 42 using the mask.

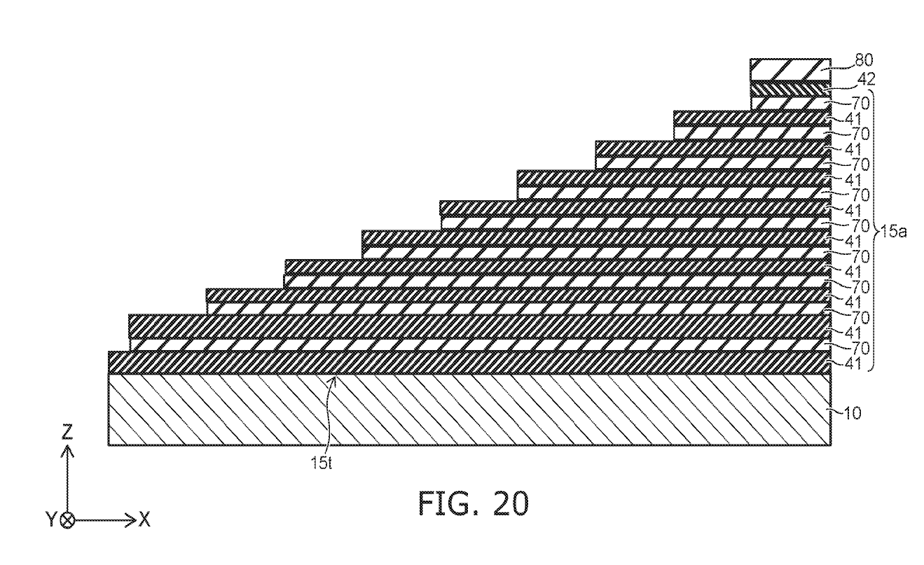

Then, as shown in FIG. 20, the end part 15t of the stacked body 15a is processed to have the stepped shape. Thus, the insulating films 42, 80 partially removed are formed in sequence on the end part 15t having the stepped shape.

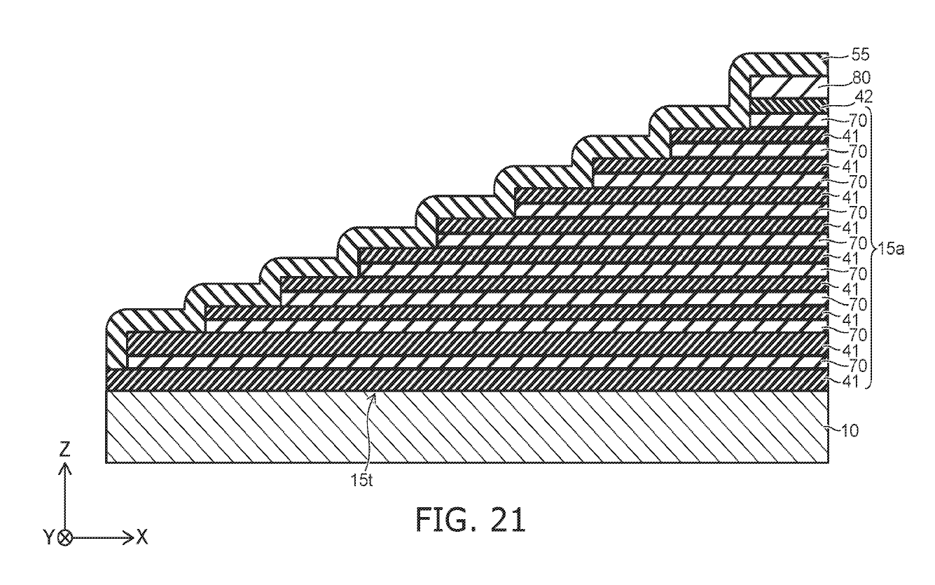

Then, as shown in FIG. 21, the insulating film 55 is formed so as to cover the end part 15t of the stacked body 15a. A part of the insulating film 55 is formed on the insulating film 80.

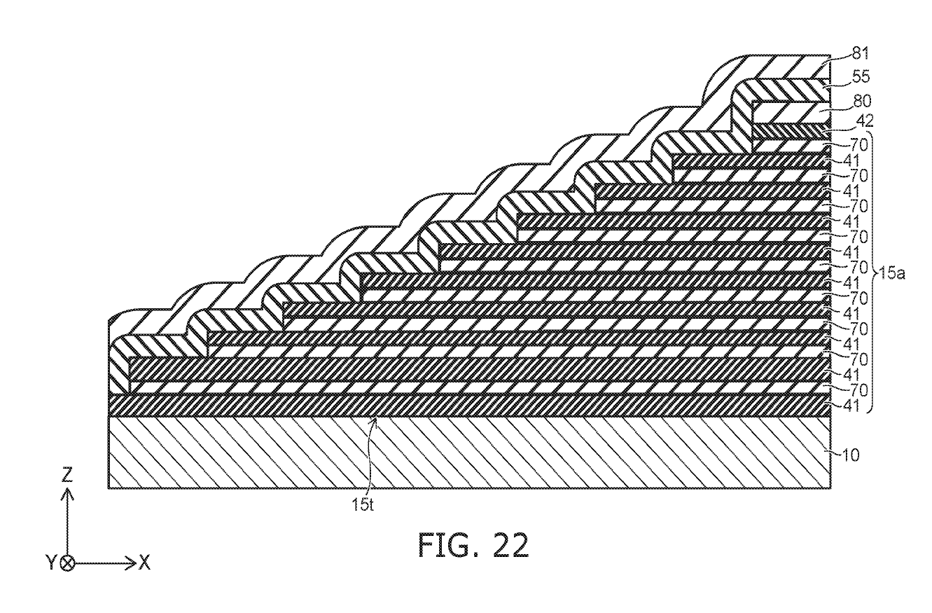

Then, as shown in FIG. 22, the insulating film 81 is formed on the insulating film 55.

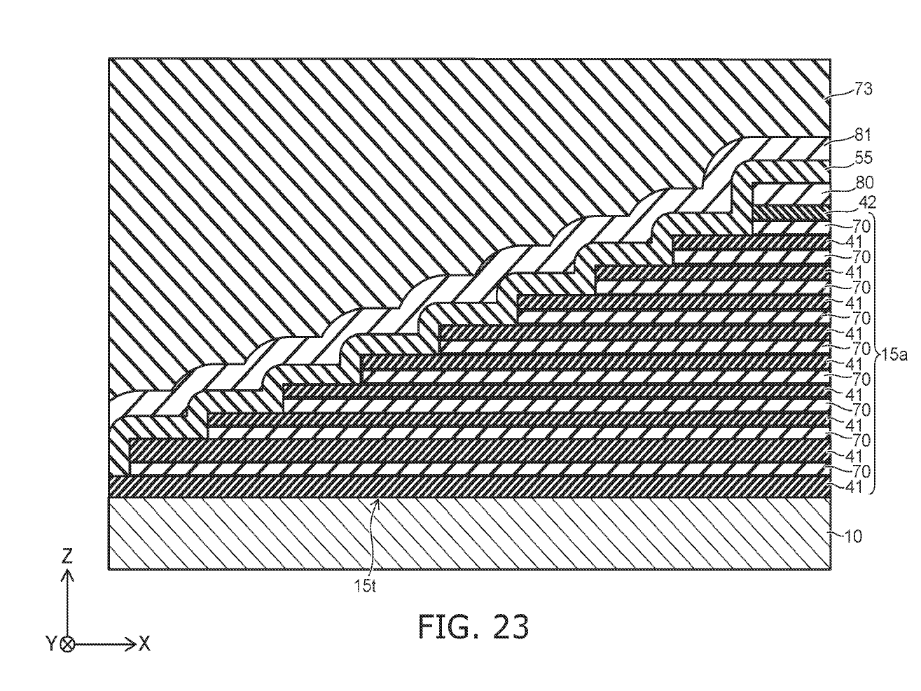

Then, as shown in FIG. 23, the insulating film 73 is formed on the insulating film 81.

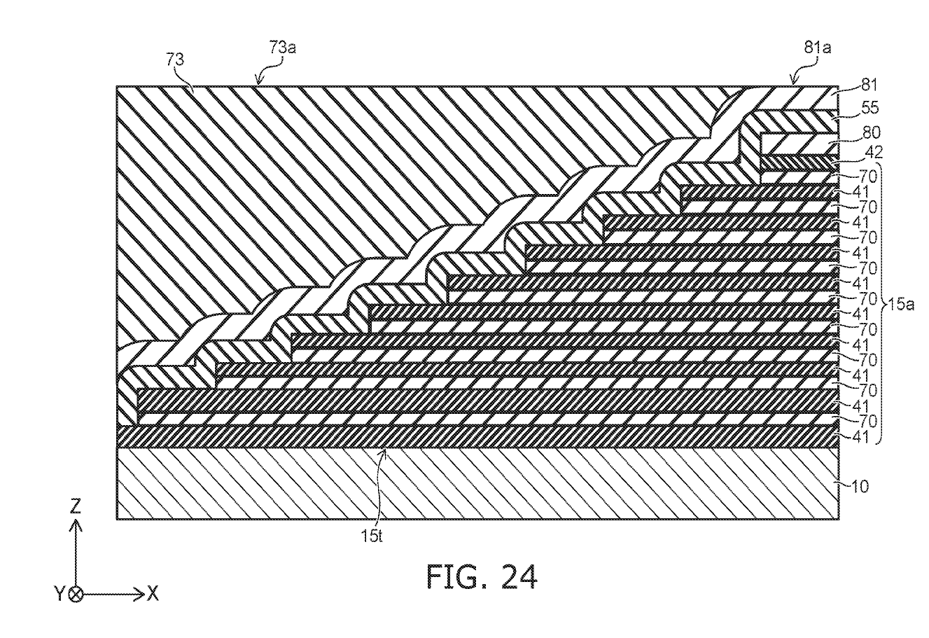

Then, as shown in FIG. 24, a part of the insulating film is removed to achieve planarization. Due to the planarization process, the upper surface 81a of the insulating film 81 located above the insulating film 80 is located on roughly the same plane as the upper surface 73a of the insulating film 73.

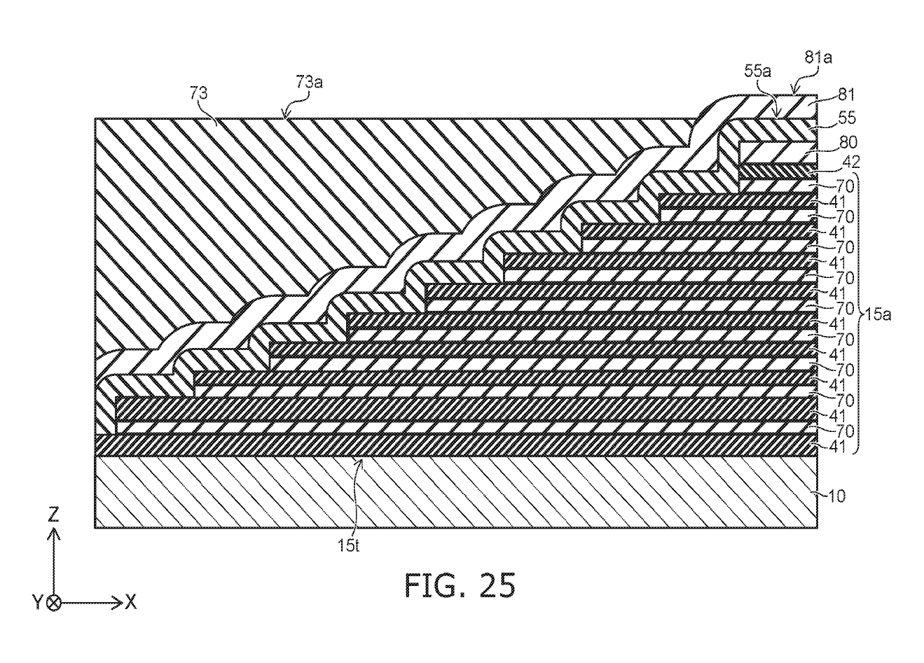

Then, as shown in FIG. 25, the insulating film 73 is etched back. Thus, the upper surface 55a of the insulating film 55 on the insulating film 80 is located on roughly the same plane as the upper surface 73a of the insulating film 73.

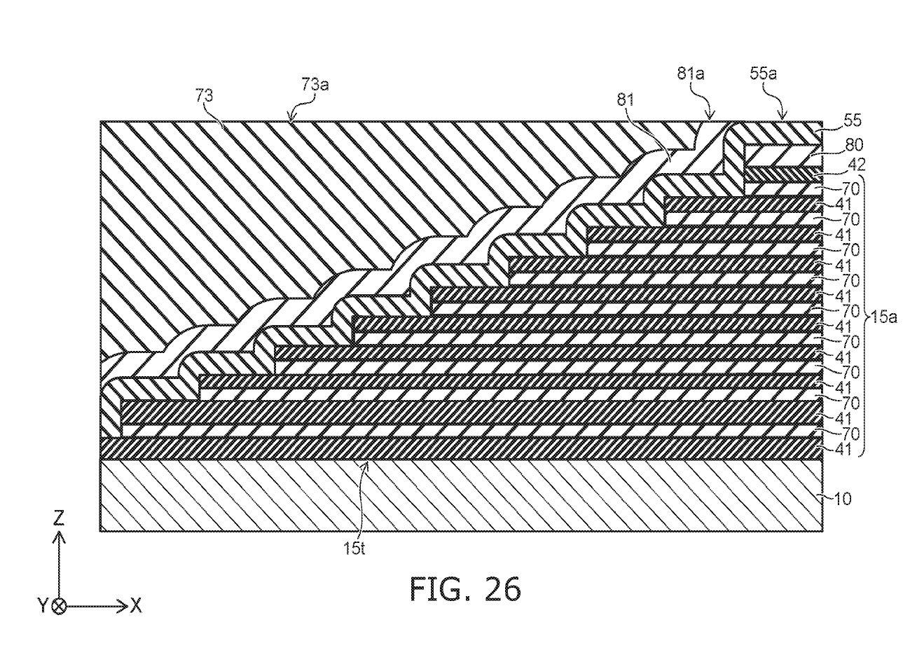

Then, as shown in FIG. 26, a part of the insulating film 81 is removed. Thus, the upper surface 81a of the insulating film 81 is located on roughly the same plane as the upper surface 55a of the insulating film 55, and the upper surface 73a of the insulating film 73.

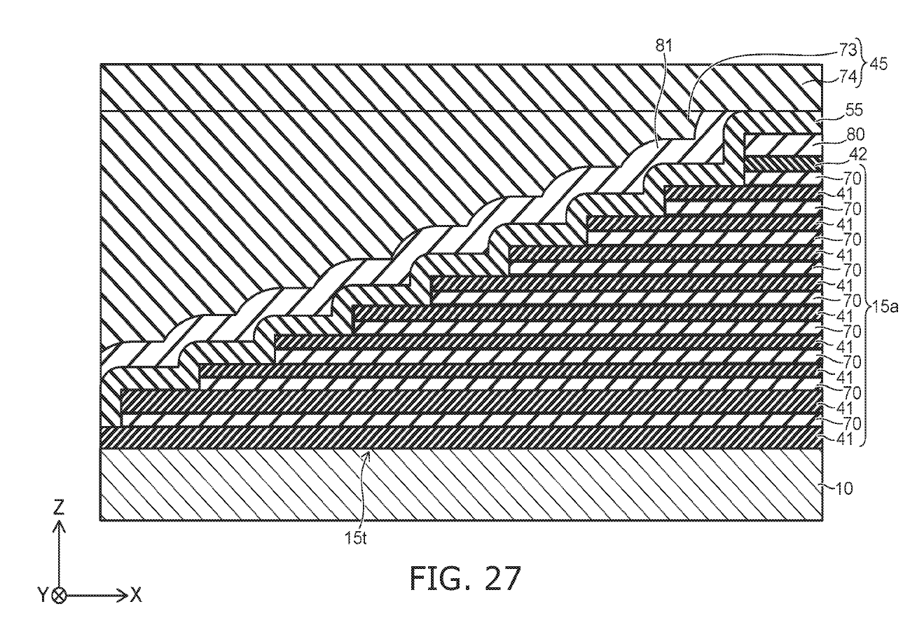

Then, as shown in FIG. 27, the insulating film 74 is formed on the insulating films 55, 73, 81. Thus, the insulating film 45 having the insulating film 73 and the insulating film 74 is formed.

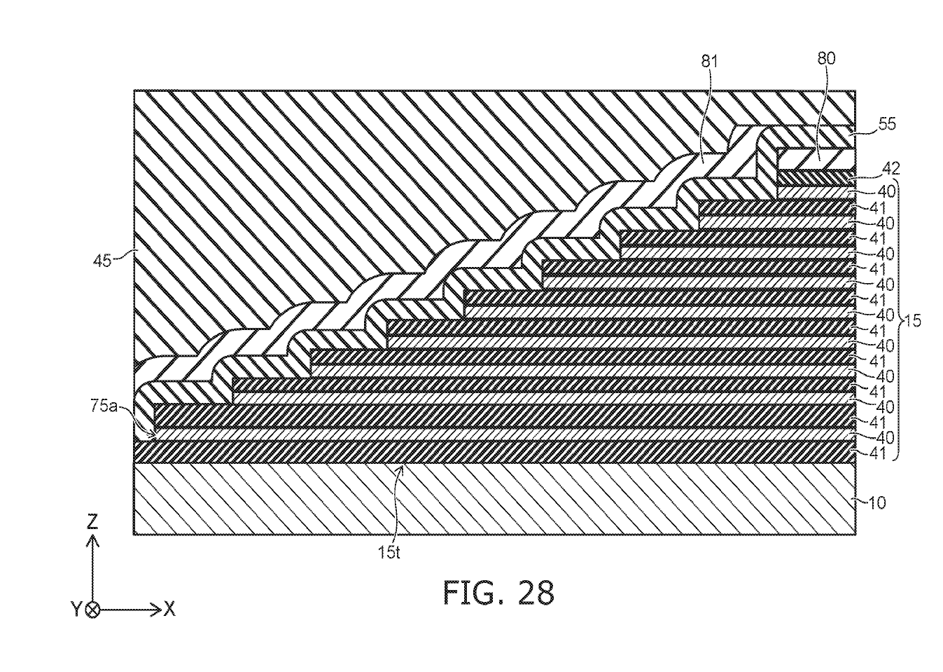

Then, as shown in FIG. 28, a plurality of slits ST extending in the X-direction and the Z-direction is provided to the stacked body 15a. The stacked body 15a is segmentalized by the slits ST into a plurality of stacked bodies each extending in the X-direction. Further, the insulating films 45, 55, 80, 81 are each segmentalized by the slits ST.

Subsequently, wet-etching is performed via the slits ST to thereby remove the sacrificial films 70. By removing the sacrificial films 70 via the slits ST, hollows 75a are formed. It should be noted that since the insulating films 80, 81 (e.g., aluminum oxide films) are different in constituent material from the sacrificial films 70 (e.g., silicon nitride films), the insulating films 80, 81 remain unetched. Subsequently, metal is deposited via the slits ST to fill in the hollows 75a to form the electrode films 40. Thus, the stacked body 15 is formed between the slits ST. Subsequently, the interconnection part 18 is formed in each of the slits ST.

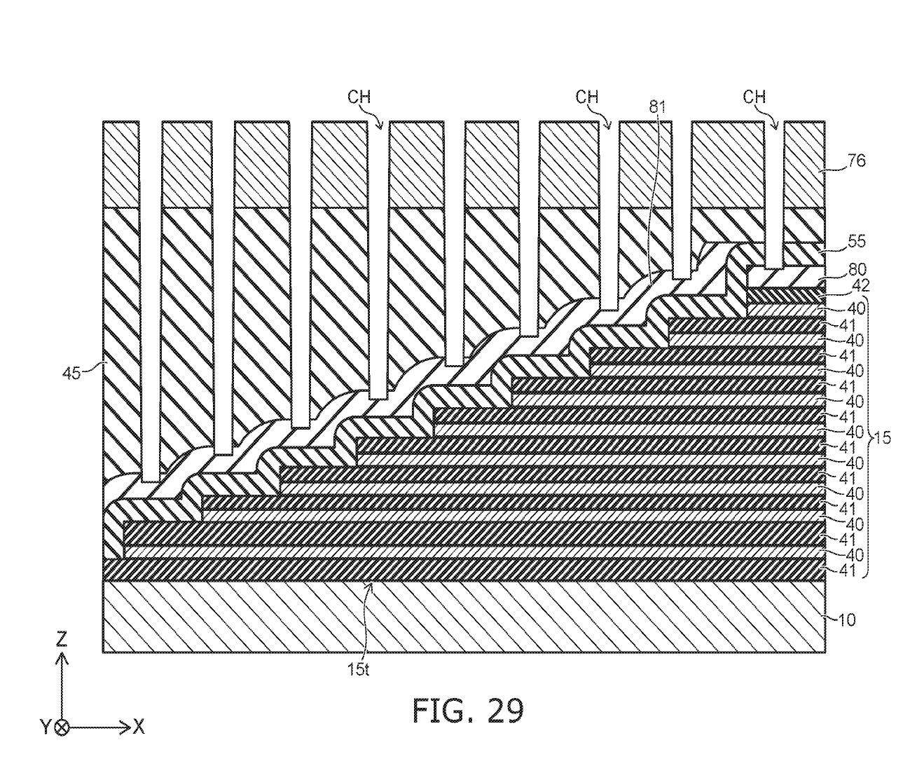

Then, as shown in FIG. 29, the insulating film 76 is formed on the insulating film 45. Subsequently, the contact holes CH are formed in the insulating films 45, 55, 76. The contact hole CH provided to the uppermost layer of the stacked body 15 penetrates the insulating films 76, 45, 55 and reaches the insulating film 80. The contact holes CH provided to other layers than the uppermost layer of the stacked body 15 penetrate the insulating films 76, 45 and reach the insulating film 81.

It is possible to stop etching without penetrating the insulating films 80, 81 by the insulating film 76 thickly formed on the insulating film 45, and the etching selectivity between the insulating film 45 (e.g., a TEOS film) and the insulating films 80, 81 (e.g., aluminum oxide films). In other words, the insulating films 80, 81 function as films for stopping etching.

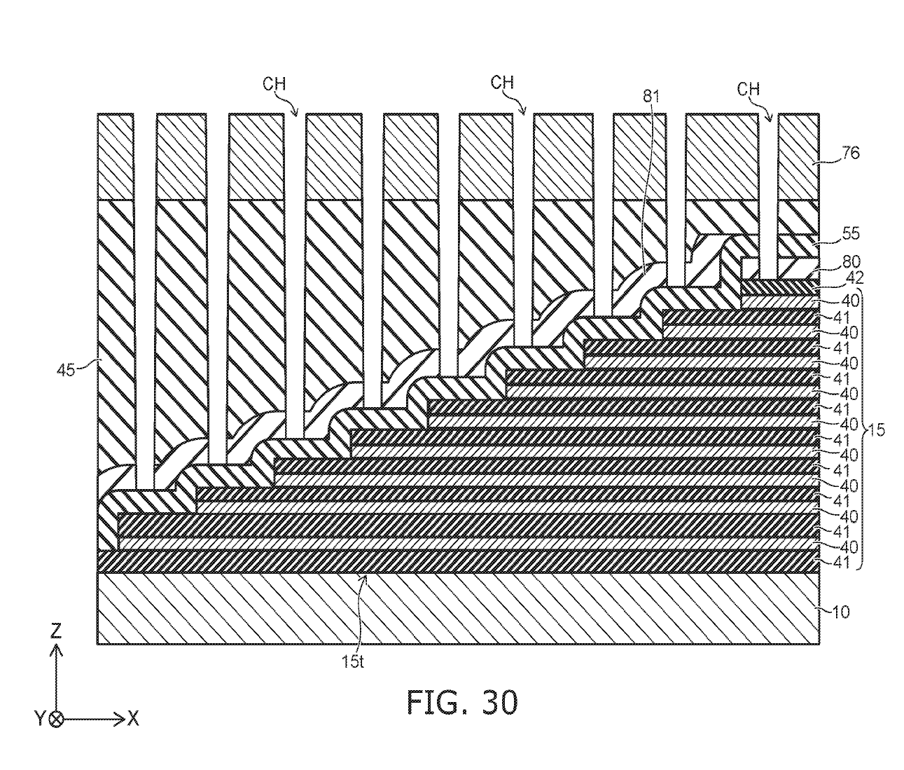

Then, as shown in FIG. 30, the insulating films 80, 81 located immediately below the contact holes CH are removed. Thus, the contact hole CH provided to the uppermost layer of the stacked body 15 penetrates the insulating film 80 to reach the insulating film 42. The contact holes CH provided to other layers than the uppermost layer of the stacked body 15 penetrate the insulating film 81 and reach the insulating film 55. The etching conditions between the insulating films 80, 81 and the insulating films 42, 55 are set so as not to penetrate the insulating films 42, 55. It should be noted that a part of the insulating film 76 is removed together with the removal of the insulating films 80, 81.

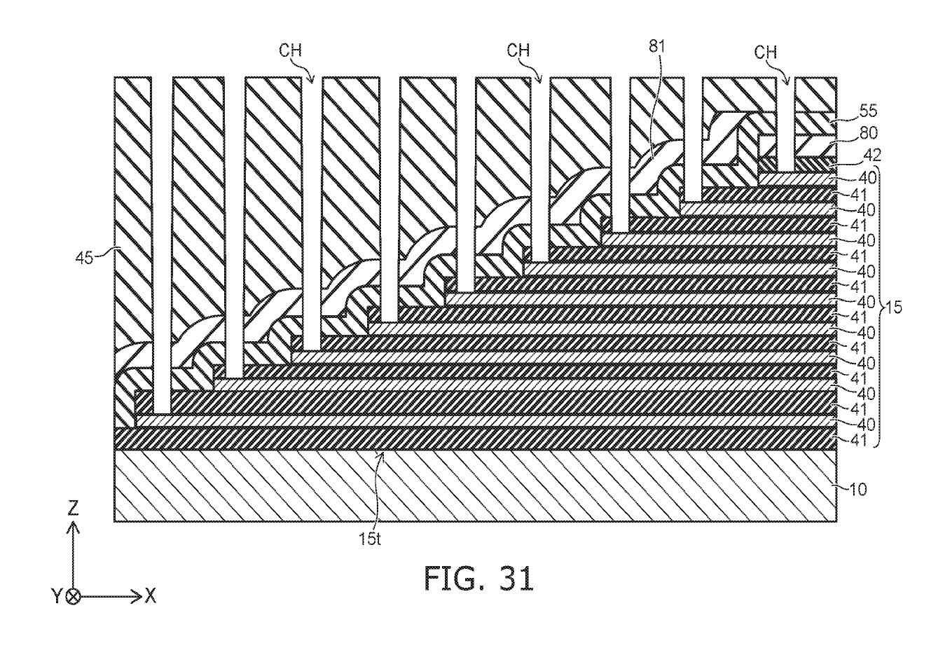

Then, as shown in FIG. 31, the insulating films 41, 42, 55 located immediately below the contact holes CH are removed. Thus, the contact holes CH reach the respective electrode films 40. It should be noted that a part of the insulating film 76 is removed together with the removal of the insulating films 41, 42, 55.

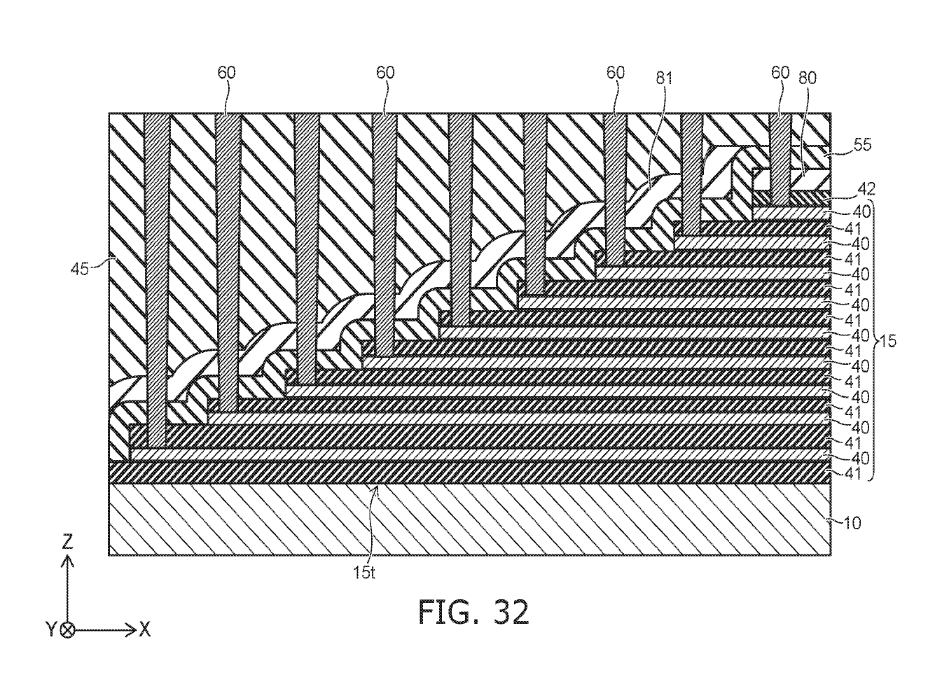

Then, as shown in FIG. 32, metal is deposited in the contact holes CH to form the contacts 60. It should be noted that since the contacts 60 are electrically isolated from the insulating films 80, 81, the spacer 61 is not formed.

The semiconductor memory device 2 is manufactured in such a manner as described above.

Then, advantages of the embodiment will be described.

In the embodiment, the semiconductor memory device 2 has the insulating film 80 and the insulating film 55 provided on the end part 15t having the stepped shape of the stacked body 15, and the insulating film 81 provided on the insulating film 55. The insulating films 80, 81 disposed in such a manner function as films for stopping etching as shown in FIG. 29. Thus, as shown in FIG. 30 and FIG. 31, it is possible to make the insulating films (the insulating films 41, 42, 55), which are etched once again after the etching is once stopped by the insulating films 80, 81, roughly equal in thickness to each other from the upper-layer electrode film 40 to the lower-layer electrode film 40. Then, by etching these insulating films in a step-by-step manner from the upper-layer electrode film 40 to the lower-layer electrode film 40, it is possible to prevent the contact holes CH from penetrating the electrode films 40 and the insulating films 41 immediately below the respective electrode films 40. Therefore, it is possible to prevent the short circuit between the electrode films 40, which occurs due to the penetration by the contact hole CH.

It should be noted that it is also possible to provide the conductive part (the conductive films 50, 51) as in the first embodiment instead of the insulating part (the insulating films 80, 81). In this case, in the process shown in FIG. 28, it results that the conductive films 50, 51 remain unetched similarly to the insulating films 80, 81 remained unetched in the etching process via the slits ST. Further, as in the process shown in FIG. 29, the conductive films 50, 51 function as films for stopping etching. The electrode films 50, 51 each include metal such as tungsten or molybdenum. The conductive films 50, 51 include, for example, polysilicon.

### Third Embodiment

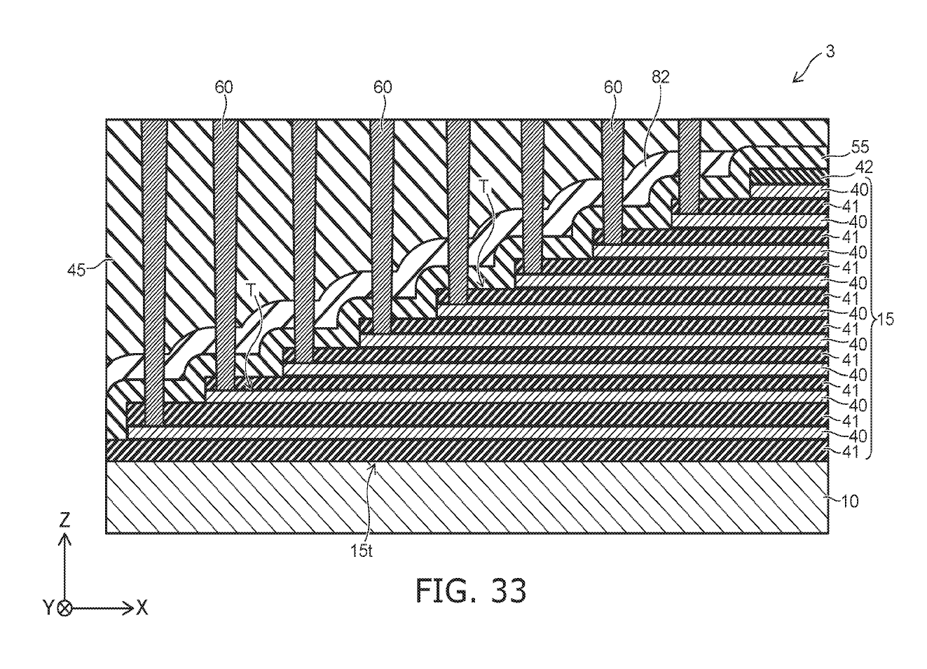

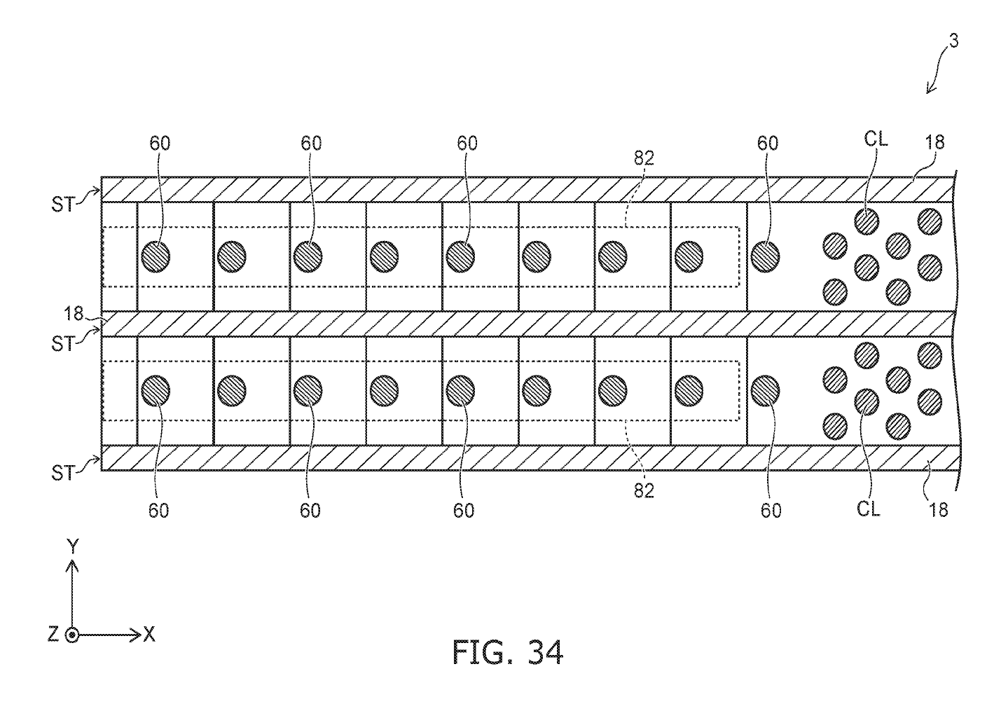

FIG. 33 is a cross-sectional view showing a semiconductor memory device 3. FIG. 34 is a top view of the semiconductor storage device 3, and shows an upper surface of the area shown in FIG. 33. The area shown in FIG. 33 corresponds to the area showing the end part 15t of the stacked body 15 in FIG. 1, and the area shown in FIG. 34 corresponds to the area shown in FIG. 2.

As shown in FIG. 33 and FIG. 34, the semiconductor memory device 3 according to the embodiment is different in the point that an insulating films 82 is provided instead of the conductive part (the conductive films 50, 51) compared to the semiconductor memory device 1 according to the first embodiment.

The semiconductor memory device 3 is provided with the insulating film 55, the insulating film 82, and the plurality of contacts 60. The insulating film 55, the insulating film 82 and the contacts 60 are provided on the end part 15t of the stacked body 15.

The insulating film 55 covers the end part 15t of the stacked body 15 so that a part of the insulating film 55 is located on the insulating film 42.

The insulating film 82 is provided on a part of the insulating film 55. Specifically, the insulating film 82 is not provided on the insulating film 55 located on the insulating film 43. As indicated by the dotted lines in FIG. 34, the insulating film 82 is located between the slits ST. When viewed from the Z-direction, at least a part of the insulating film 82 overlaps the contacts 60.

Although the shape of the insulating film 82 is a rectangular shape when viewed from the Z-direction in the example shown in FIG. 34, the shape of the insulating film 82 is not limited to this example. The insulating film 82 includes, for example, silicon nitride.

The contacts 60 are respectively located on the terraces T of the electrode films 40, and extend in the Z-direction in the end part 15t of the stacked body 15. The contact 60 is not provided on the terrace T of the electrode film 40 as the uppermost layer. The contacts 60 located on the terraces T of the electrode films 40 except the electrode film 40 as the uppermost layer each penetrate the insulating films 45, 82, 55, 42.

It should be noted that unlike the first embodiment, the spacer 61 is not provided on the periphery of the contact 60 in the embodiment.

Then, a method of manufacturing the semiconductor memory device according to the embodiment will be described.

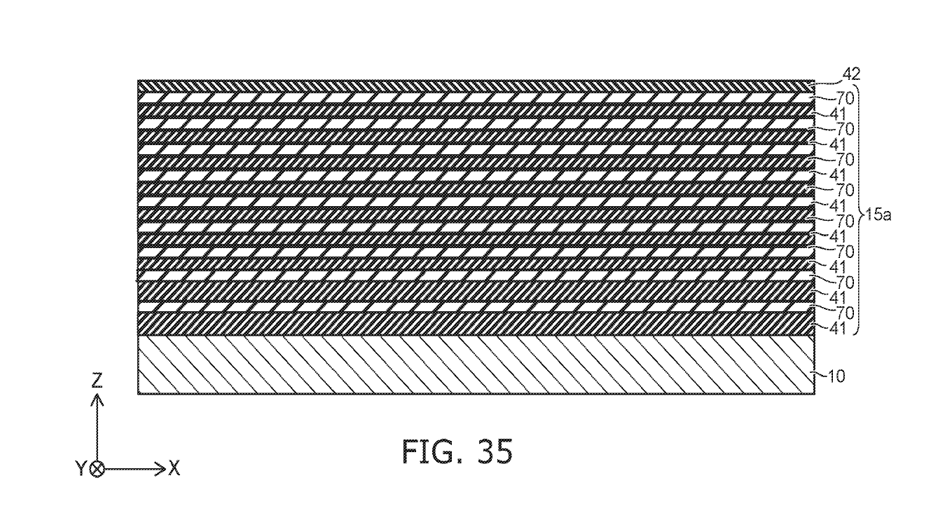

FIG. 35 through FIG. 38 and FIG. 40 through FIG. 49 are cross-sectional views showing the method of manufacturing the semiconductor memory device 3.

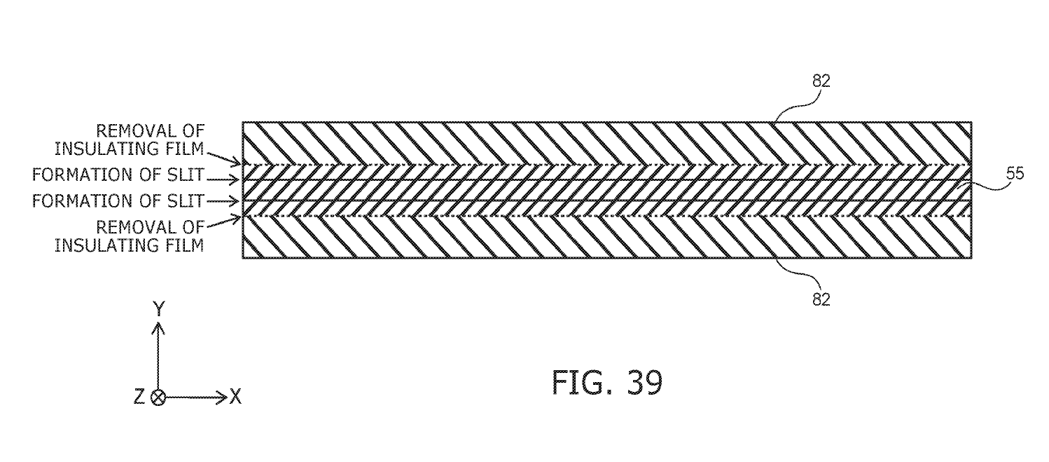

FIG. 39 is a top view showing the method of manufacturing the semiconductor memory device 3.

FIG. 35 through FIG. 38 and FIG. 40 through FIG. 49 each show the area corresponding to FIG. 33. FIG. 39 shows a part of the area shown in FIG. 34 in the process of forming the slits ST.

Firstly, as shown in FIG. 35, the insulating films 41 and the sacrificial films 70 are alternately stacked on one another along the Z-direction to form the stacked body 15a on the substrate 10. Subsequently, the insulating film 42 is formed on the stacked body 15a.

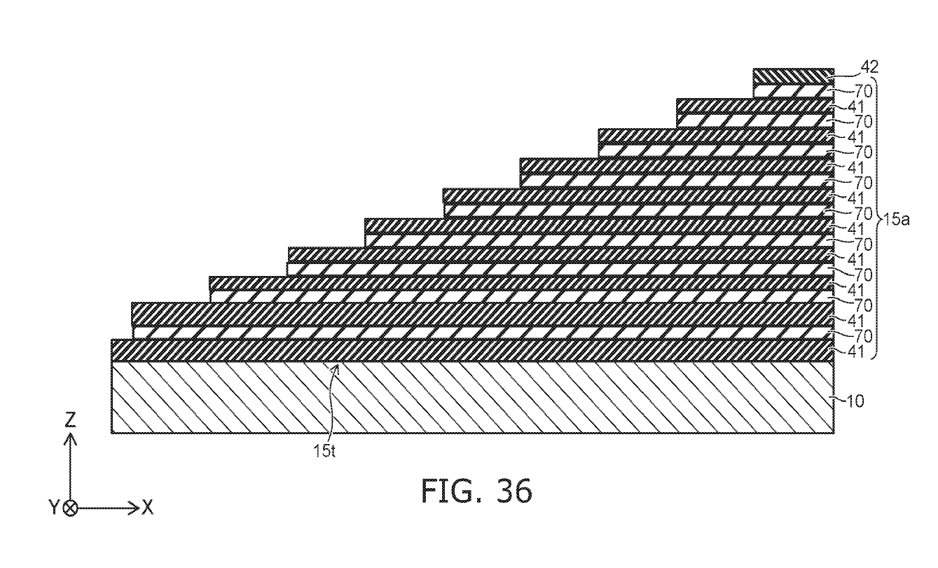

Then, as shown in FIG. 36, the end part 15t of the stacked body 15a is processed to have the stepped shape. Thus, the insulating film 42 partially removed is formed on the end part 15t having the stepped shape.

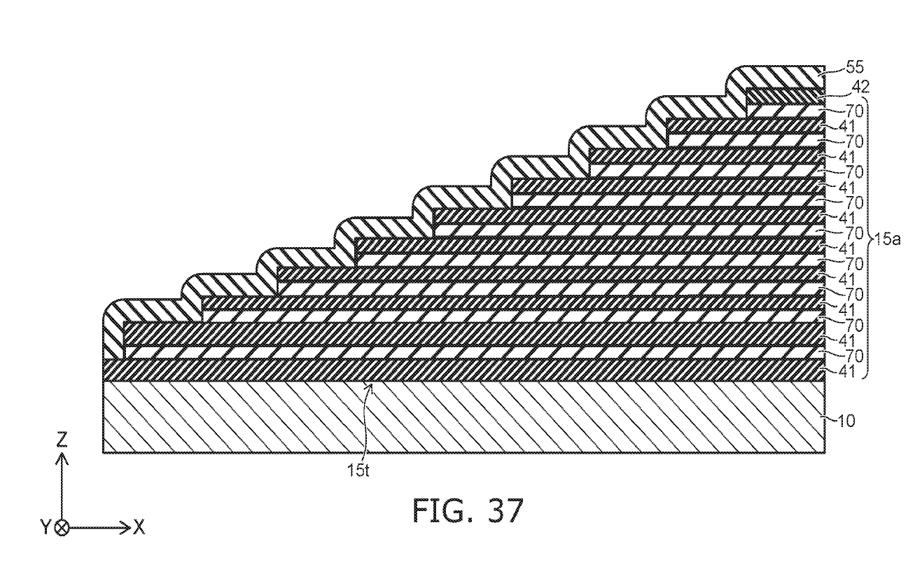

Then, as shown in FIG. 37, the insulating film 55 is formed so as to cover the end part 15t of the stacked body 15a. A part of the insulating film 55 is formed on the insulating film 42.

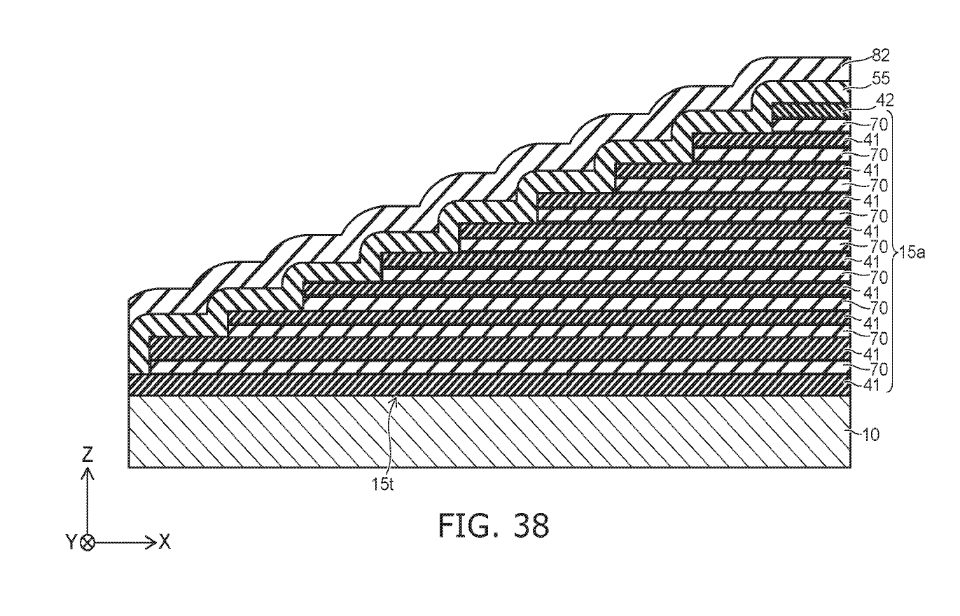

Then, as shown in FIG. 38, the insulating film 82 is formed on the insulating film 55. Subsequently, a part of the insulating film 82 is removed by the photolithography method using a mask and so on and an etching process such as RIE.

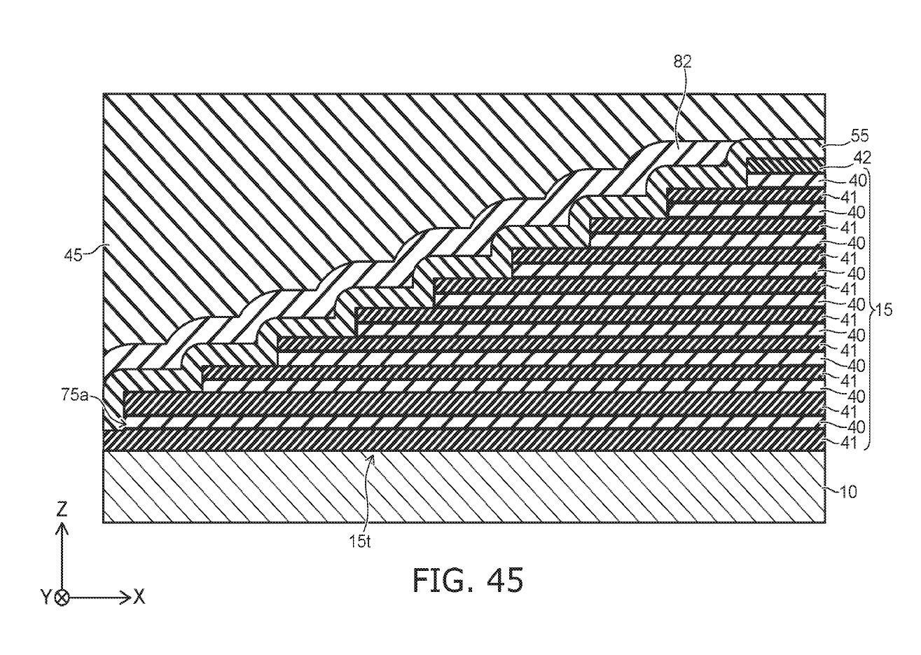

As shown in FIG. 39, the insulating film 82 is formed on the entire surface of the insulating film 55, and is then removed up to the parts indicated by the dotted lines on the both sides in the Y-direction. Further, the part indicated by the solid lines corresponds to a part where the slit ST is formed in the process shown in FIG. 45 described later. In other words, by removing the part of the insulating film 82, the insulating film 82 is formed on the inner side than the slit ST.

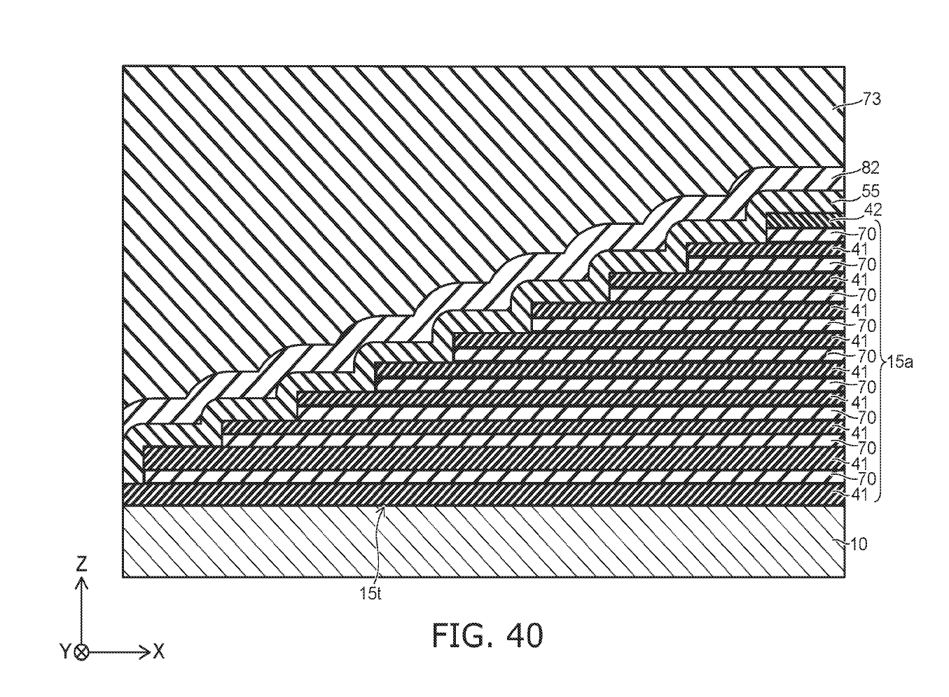

Then, as shown in FIG. 40, the insulating film 73 is formed on the insulating film 82.

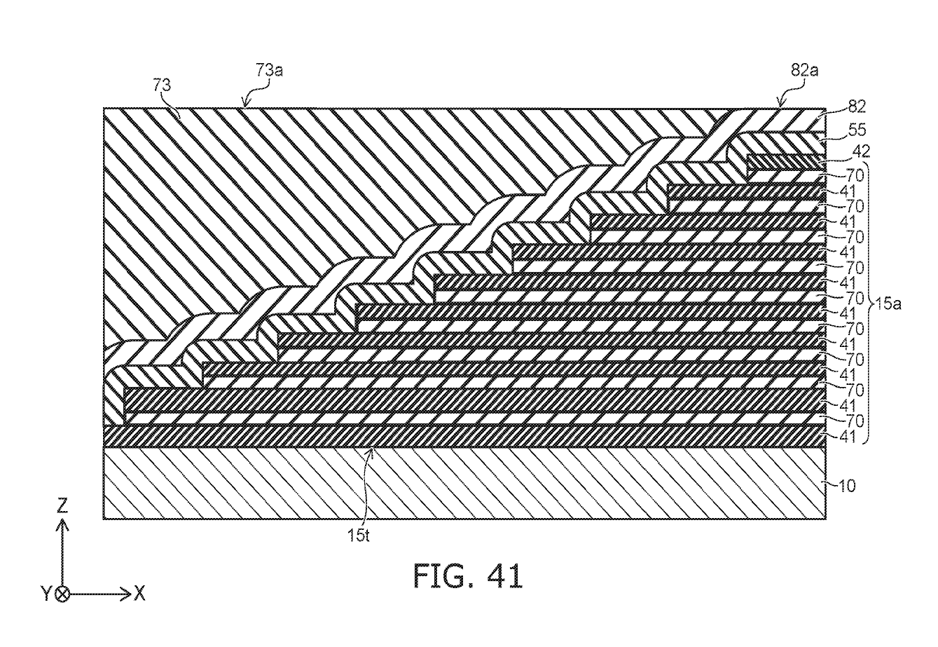

Then, as shown in FIG. 41, a part of the insulating film is removed to achieve planarization. Due to the planarization process, the upper surface 82a of the insulating film 82 located above the insulating film 55 is located on roughly the same plane as the upper surface 73a of the insulating film 73.

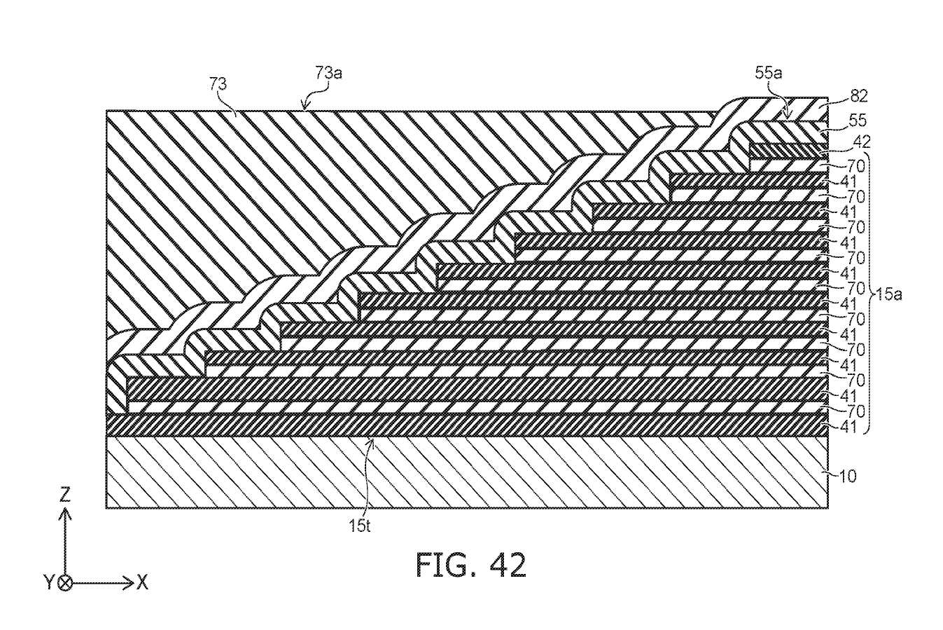

Then, as shown in FIG. 42, the insulating film 73 is etched back. Thus, the upper surface 55a of the insulating film 55 on the insulating film 42 is located on roughly the same plane as the upper surface 73a of the insulating film 73.

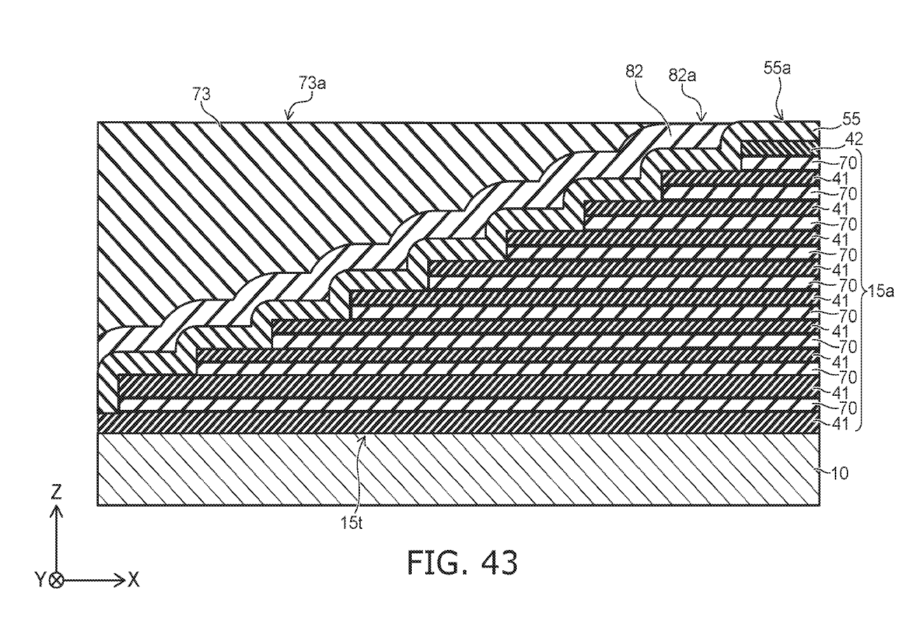

Then, as shown in FIG. 43, a part of the insulating film 82 is removed. Thus, the upper surface 82a of the insulating film 82 is located on roughly the same plane as the upper surface 55a of the insulating film 55, and the upper surface 73a of the insulating film 73.

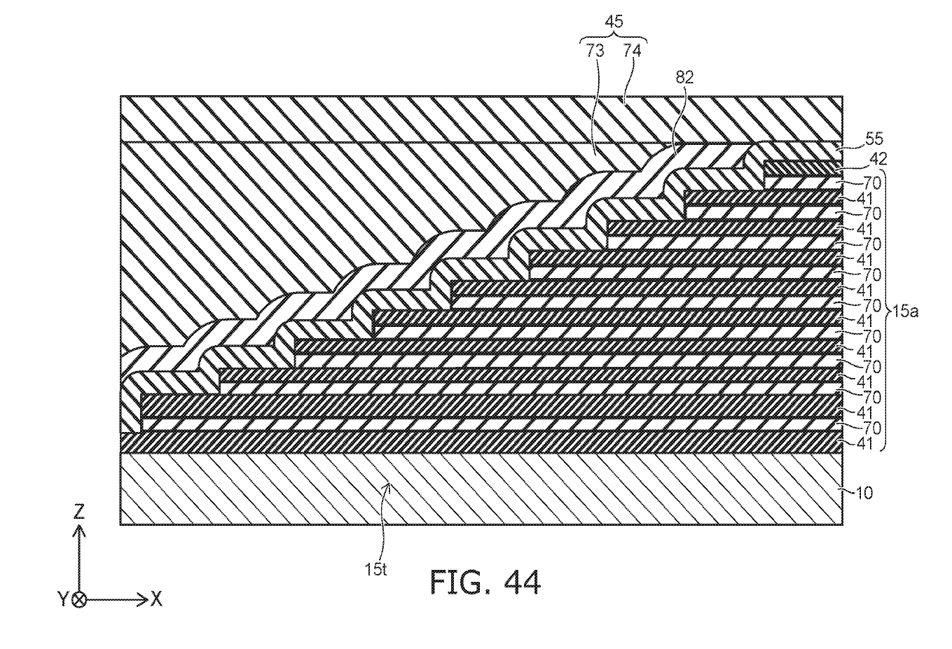

Then, as shown in FIG. 44, the insulating film 74 is formed on the insulating films 55, 73, 82. Thus, the insulating film 45 having the insulating film 73 and the insulating film 74 is formed.

Then, as shown in FIG. 45, a plurality of slits ST extending in the X-direction and the Z-direction is provided to the stacked body 15a. The stacked body 15a is segmentalized by the slits ST into a plurality of stacked bodies each extending in the X-direction. Further, the insulating films 45, 55, 82 are each segmentalized by the slits ST.

Subsequently, wet-etching is performed via the slits ST to thereby remove the sacrificial films 70. By removing the sacrificial films 70 via the slits ST, hollows 75a are formed. It should be noted that as described above, in the process shown in FIG. 38 and FIG. 39, the insulating film 82 is formed on the inner side than the slit ST. Since the insulating film 45 (the insulating film 73) is located between the slit ST and the insulating film 82 in the Y-direction, the insulating film 82 formed of silicon nitride remains unetched. Subsequently, metal is deposited via the slits ST to fill in the hollows 75a to form the electrode films 40. Thus, the stacked body 15 is formed between the slits ST. Subsequently, the interconnection part 18 is formed in each of the slits ST.

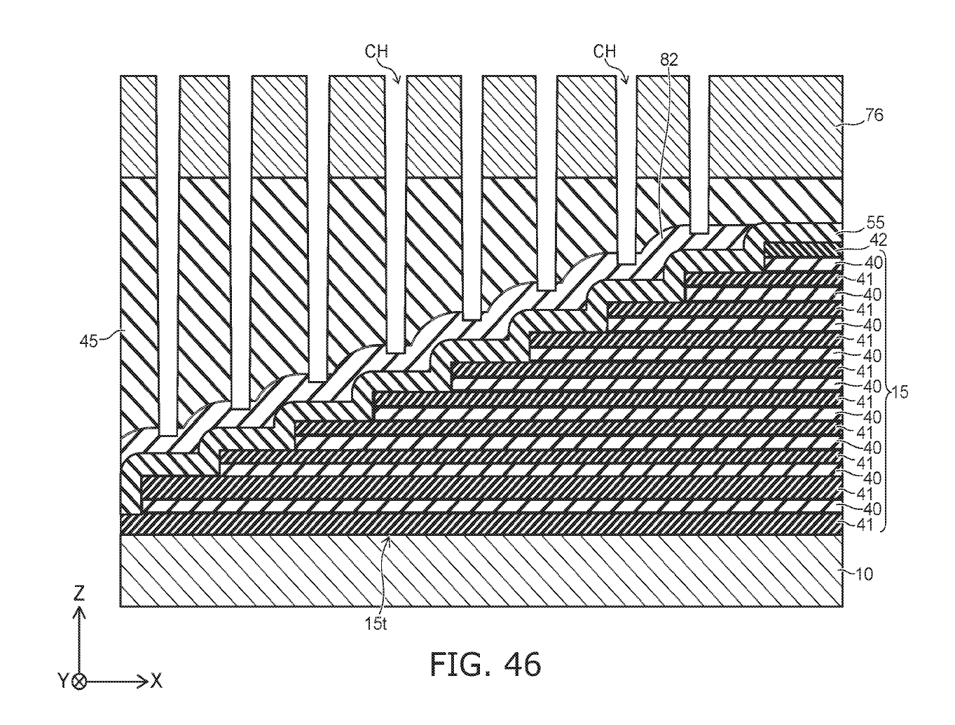

Then, as shown in FIG. 46, the insulating film 76 is formed on the insulating film 45. Subsequently, the contact holes CH are formed in the insulating films 45, 76. The contact hole CH is not provided to the uppermost layer of the stacked body 15. The contact holes CH penetrate the insulating films 76, 45 and reach the insulating film 82.

It is possible to stop etching without penetrating the insulating film 82 by the insulating film 76 thickly formed on the insulating film 45, and the etching selectivity between the insulating film 45 (e.g., a TEOS film) and the insulating film 82 (e.g., a silicon nitride film). In other words, the insulating film 82 functions as a film for stopping etching.

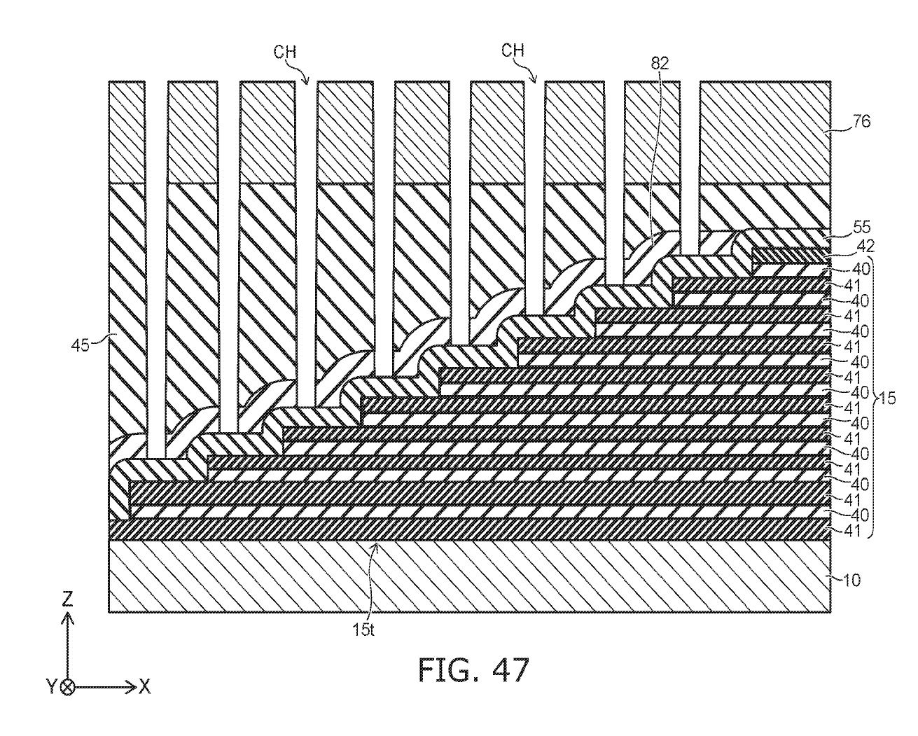

Then, as shown in FIG. 47, the insulating film 82 located immediately below the contact holes CH is removed. Thus, the contact holes CH penetrate the insulating film 82 and reach the insulating film 55. The etching conditions between the insulating film 82 and the insulating film 55 are set so as not to penetrate the insulating film 55. It should be noted that a part of the insulating film 76 is removed together with the removal of the insulating film 82.

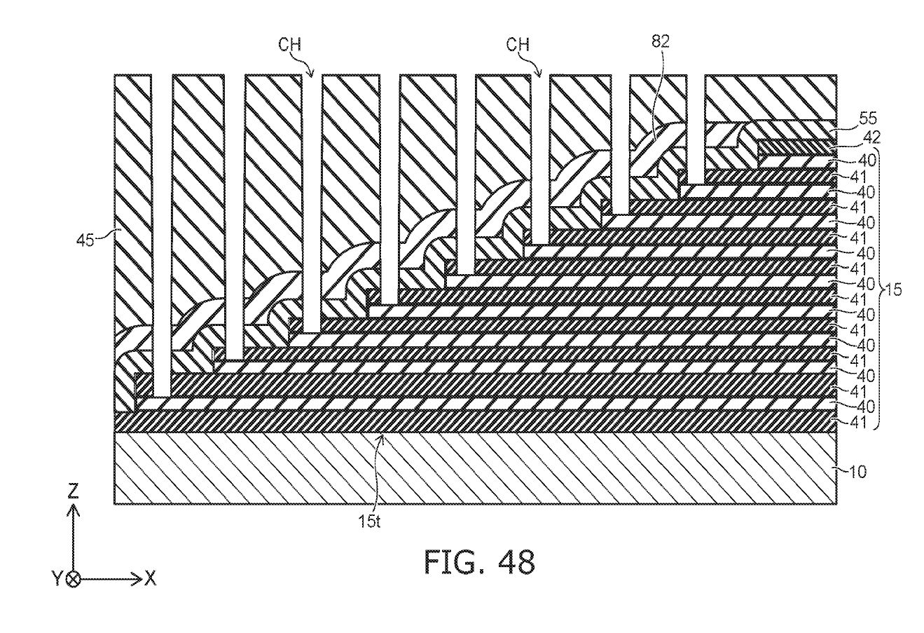

Then, as shown in FIG. 48, the insulating films 41, 55 located immediately below the contact holes CH are removed. Thus, the contact holes CH reach the respective electrode films 40. It should be noted that a part of the insulating film 76 is removed together with the removal of the insulating films 55, 41.

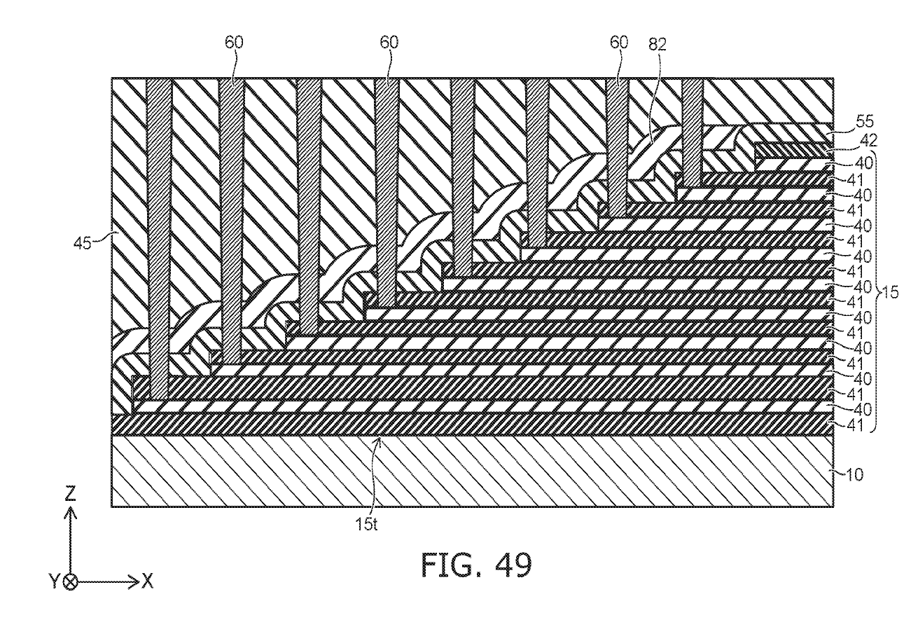

Then, as shown in FIG. 49, metal is deposited in the contact holes CH to form the contacts 60. It should be noted that since the contacts 60 are electrically isolated from the insulating film 82, the spacer 61 is not formed.

The semiconductor memory device 3 is manufactured in such a manner as described above.

Then, advantages of the embodiment will be described.

In the embodiment, the semiconductor memory device 3 has the insulating film 55 provided on the end part 15t having the stepped shape of the stacked body 15, and the insulating film 82 provided on the insulating film 55. Such an insulating film 82 functions as a film for stopping etching as shown in FIG. 46. Thus, as shown in FIG. 47 and FIG. 48, it is possible to make the insulating films (the insulating films 41, 55), which are etched once again after the etching is once stopped by the insulating film 82, roughly equal in thickness to each other from the upper-layer electrode film 40 to the lower-layer electrode film 40. Then, by etching these insulating films in a step-by-step manner from the upper-layer electrode film 40 to the lower-layer electrode film 40, it is possible to prevent the contact holes CH from penetrating the electrode films 40 and the insulating films 41 immediately below the respective electrode films 40. Therefore, it is possible to prevent the short circuit between the electrode films 40, which occurs due to the penetration by the contact hole CH.

### Fourth Embodiment

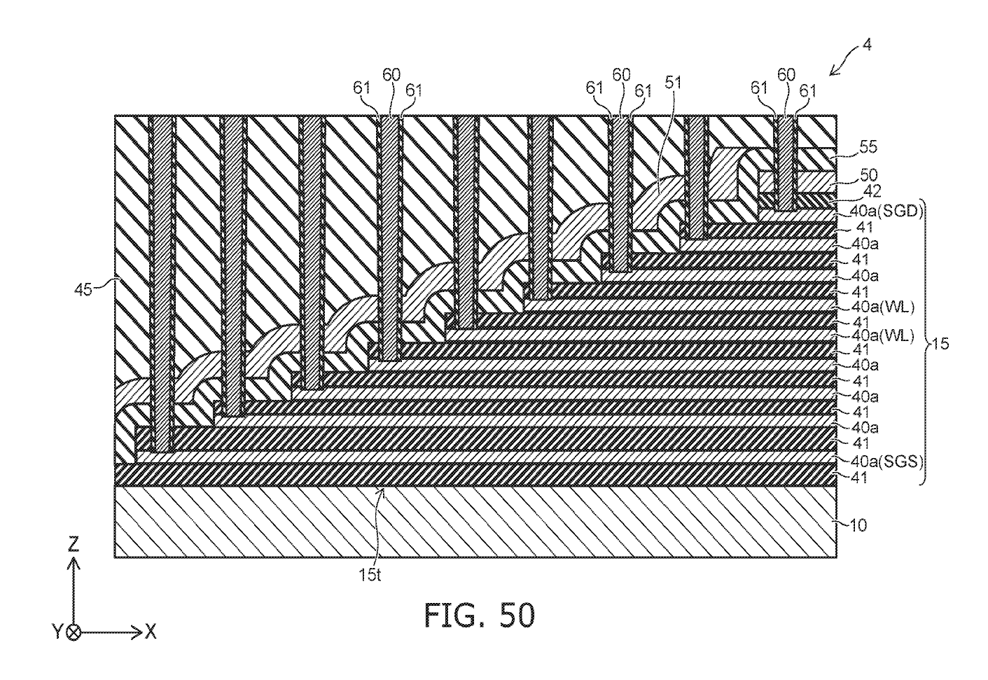

FIG. 50 is a cross-sectional view showing a semiconductor memory device 4. The area shown in FIG. 50 corresponds to the area showing the end part 15t of the stacked body 15 in FIG. 1.

As shown in FIG. 50, the semiconductor memory device 4 according to the embodiment is different in the point that the electrode films 40a are formed of polysilicon compared to the semiconductor memory device 1 according to the first embodiment.

The semiconductor memory device 4 is provided with the stacked body 15, the conductive film 50, the insulating film 55, the conductive film 51, and the plurality of contacts 60. The stacked body 15 has the electrode films 40a formed of polysilicon. The conductive film 50, the conductive film 51, the insulating film 55 and the contacts 60 are provided on the end part 15t of the stacked body 15. The conductive films 50, 51 include the same conductive material, and include metal such as tungsten or molybdenum. The conductive films 50, 51 include, for example, polysilicon.

It should be noted that it is also possible to provide the insulating films 80, 81 as in the second embodiment instead of the conductive part (the conductive films 50, 51). In other words, the insulating film 80, the insulating film 55, the insulating film 81, and the plurality of contacts 60 can be provided on the end part 15t of the stacked body 15. The insulating films 80, 81 include the same insulating material, and include at least one of, for example, aluminum oxide, hafnium oxide, and titanium oxide. Further, the insulating films 80, 81 can also include, for example, silicon nitride.

Then, a method of manufacturing the semiconductor memory device according to the embodiment will be described.

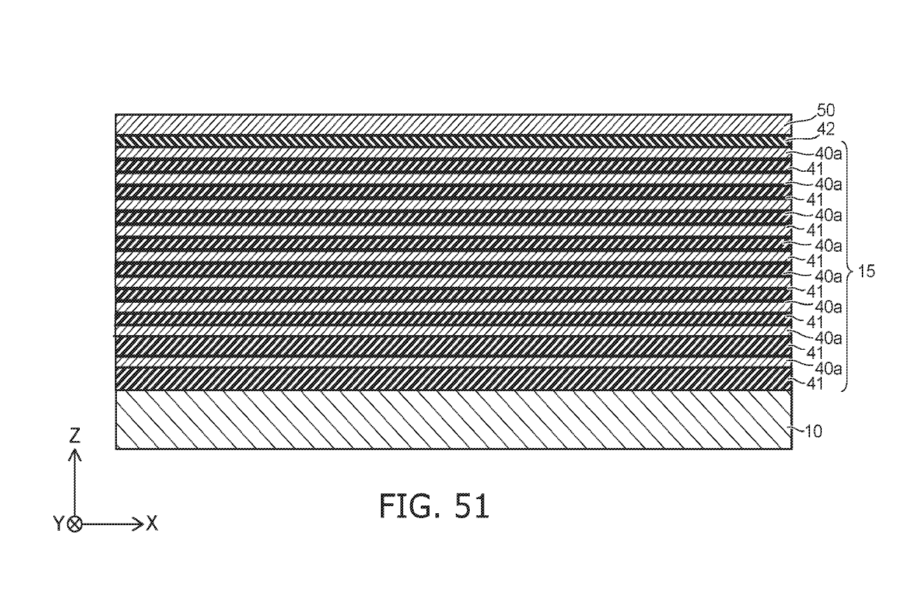

FIG. 51 through FIG. 55 are cross-sectional views showing the method of manufacturing the semiconductor memory device 4.

FIG. 51 through FIG. 55 each show the area corresponding to FIG. 50.

Firstly, as shown in FIG. 51, the insulating films 41 and the electrode films 40a are alternately stacked on one another along the Z-direction to form the stacked body 15 on the substrate 10. The electrode films 40a are formed of polysilicon. Subsequently, the insulating film 42 is formed on the stacked body 15. Subsequently, the conductive film 50 is selectively formed in the end part 15t of the stacked body 15 and on the insulating film 42 using a mask. It is also possible to form the insulating film 80 instead of forming the conductive film 50.

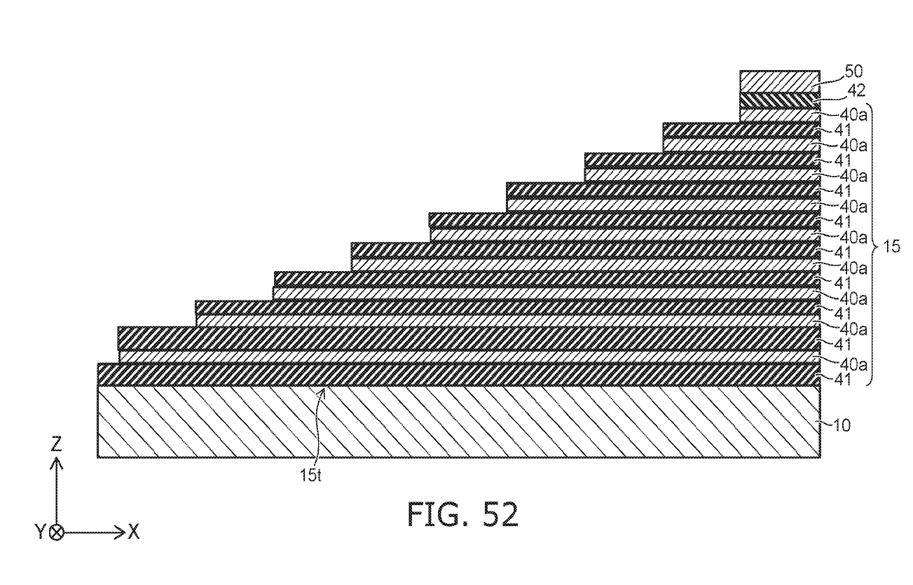

Then, as shown in FIG. 52, the end part 15t of the stacked body 15 is processed to have the stepped shape. Thus, the insulating film 42 partially removed, and the conductive films 50 are formed in sequence on the end part 15t having the stepped shape.

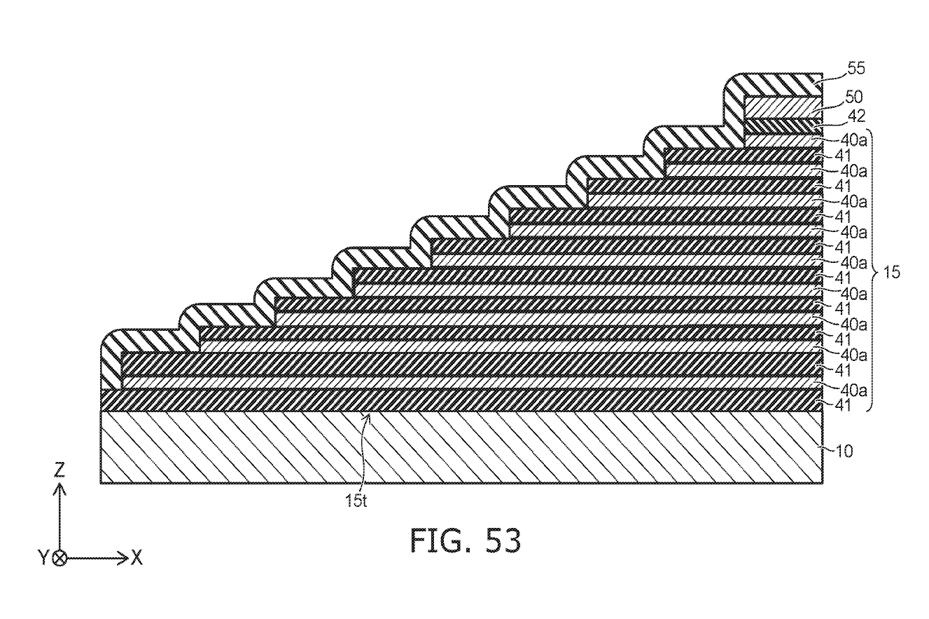

Then, as shown in FIG. 53, the insulating film 55 is formed so as to cover the end part 15t of the stacked body 15. A part of the insulating film 55 is formed on the conductive film 50.

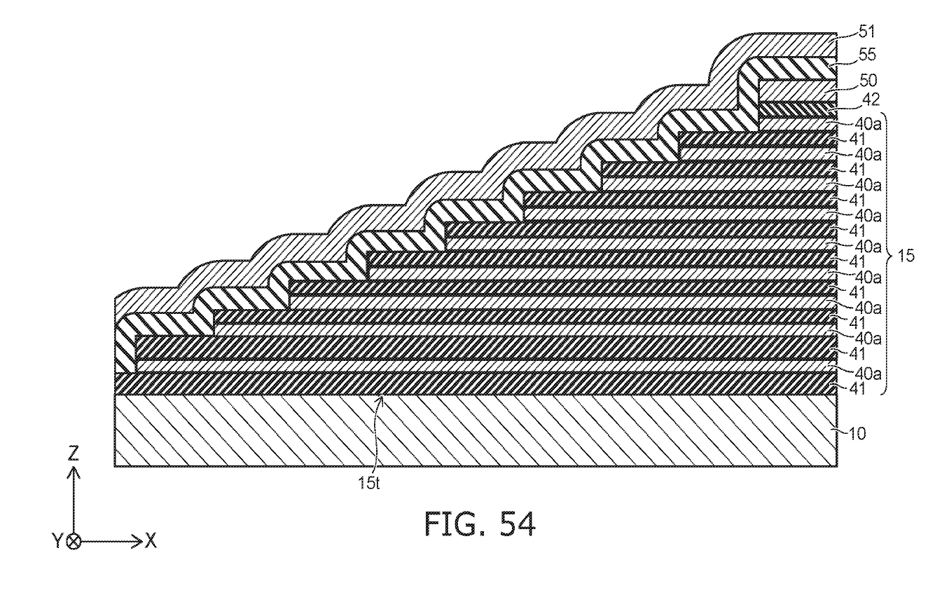

Then, as shown in FIG. 54, the conductive film 51 is formed on the insulating film 55. It is also possible to form the insulating film 81 instead of forming the conductive film 51.

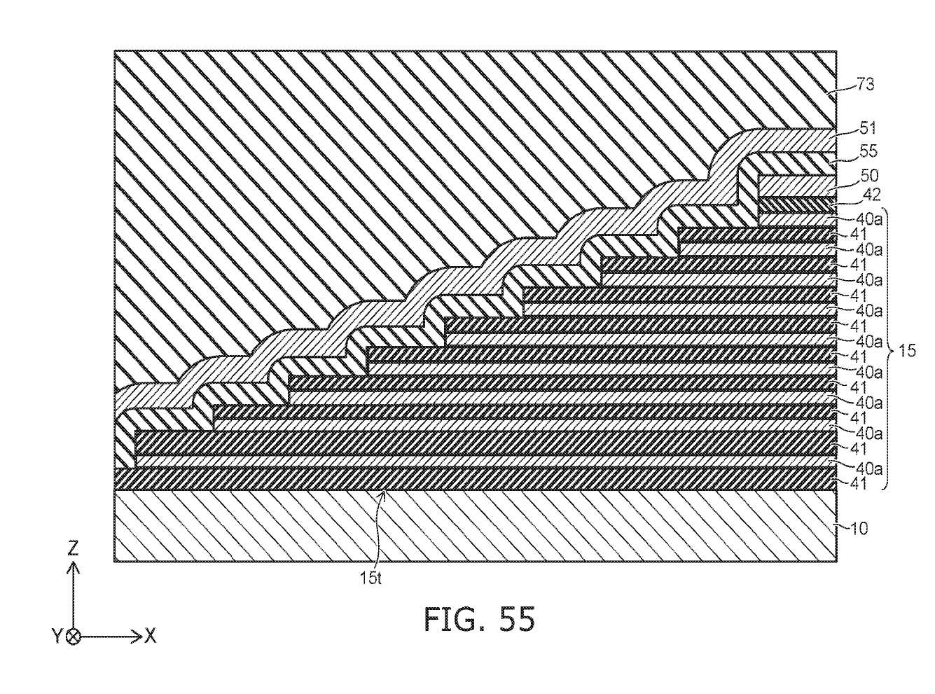

Then, as shown in FIG. 55, the insulating film 73 is formed on the conductive film 51.

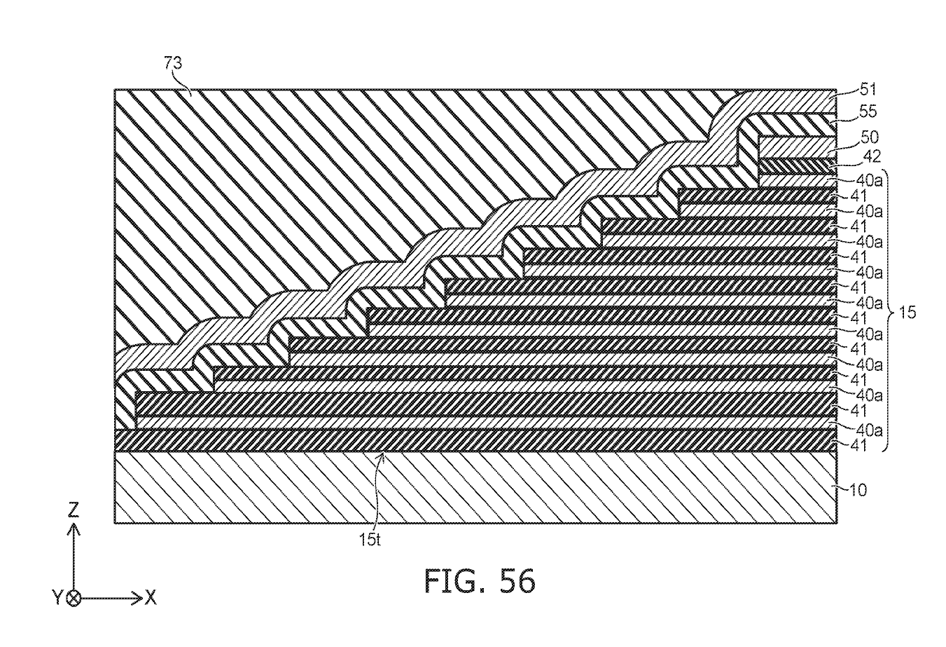

Then, as shown in FIG. 56, a part of the insulating film 73 is removed to achieve planarization.

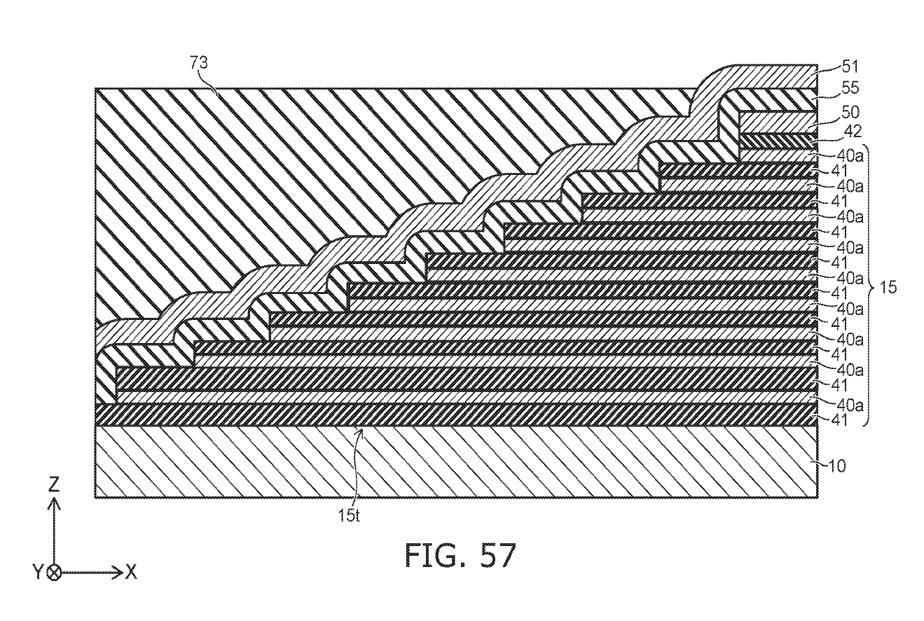

Then, as shown in FIG. 57, the insulating film 73 is etched back.

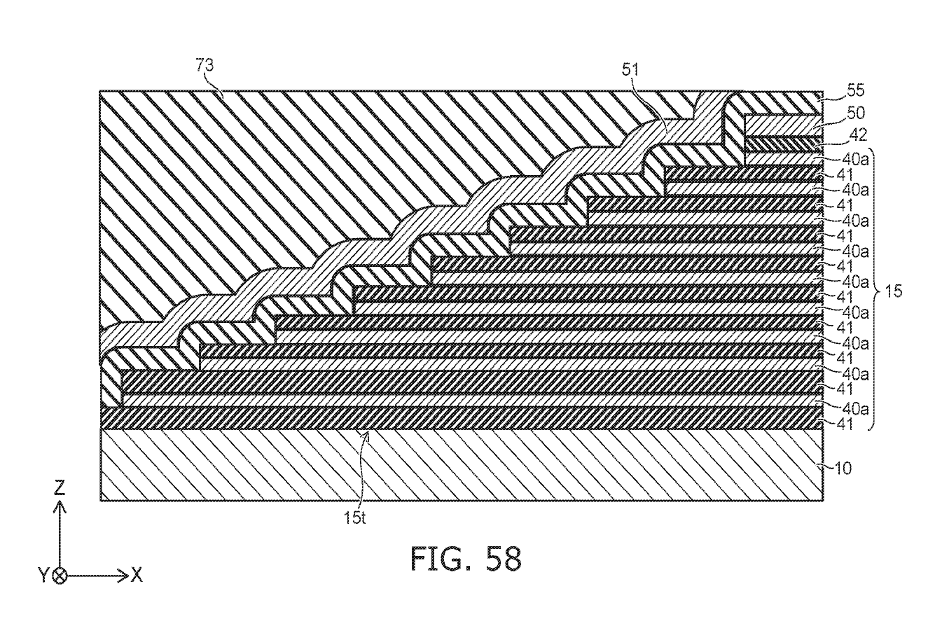

Then, as shown in FIG. 58, a part of the conductive film 51 is removed.

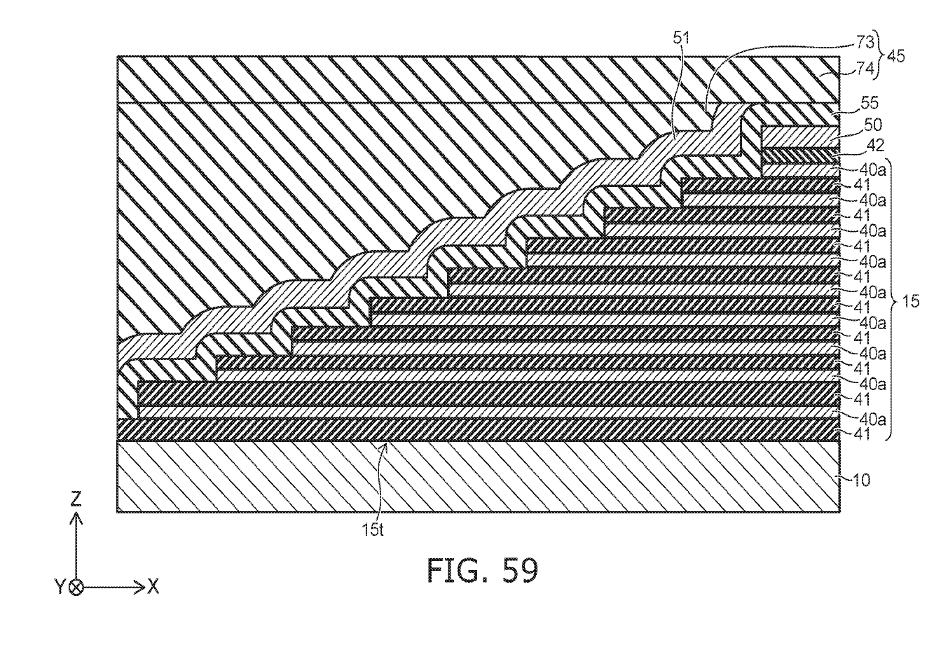

Then, as shown in FIG. 59, the insulating film 74 is formed on the insulating films 55, 73, and the conductive film 51. Thus, the insulating film 45 having the insulating film 73 and the insulating film 74 is formed. It should be noted that in the manufacturing method of the embodiment, since the electrode film 40 is formed of polysilicon, it is not necessary to perform the replacement process of the electrode films 40 via the slits ST formed after forming the insulating film 45.

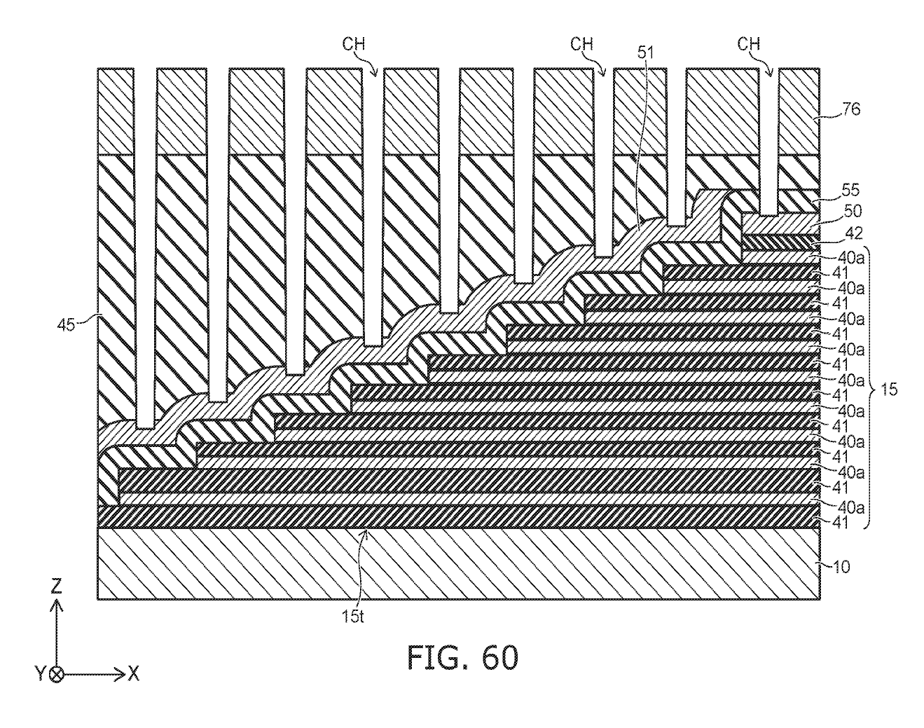

Then, as shown in FIG. 60, the insulating film 76 is formed on the insulating film 45. Subsequently, the contact holes CH are formed in the insulating films 45, 55, 76. The conductive films 50, 51 function as films for stopping etching.

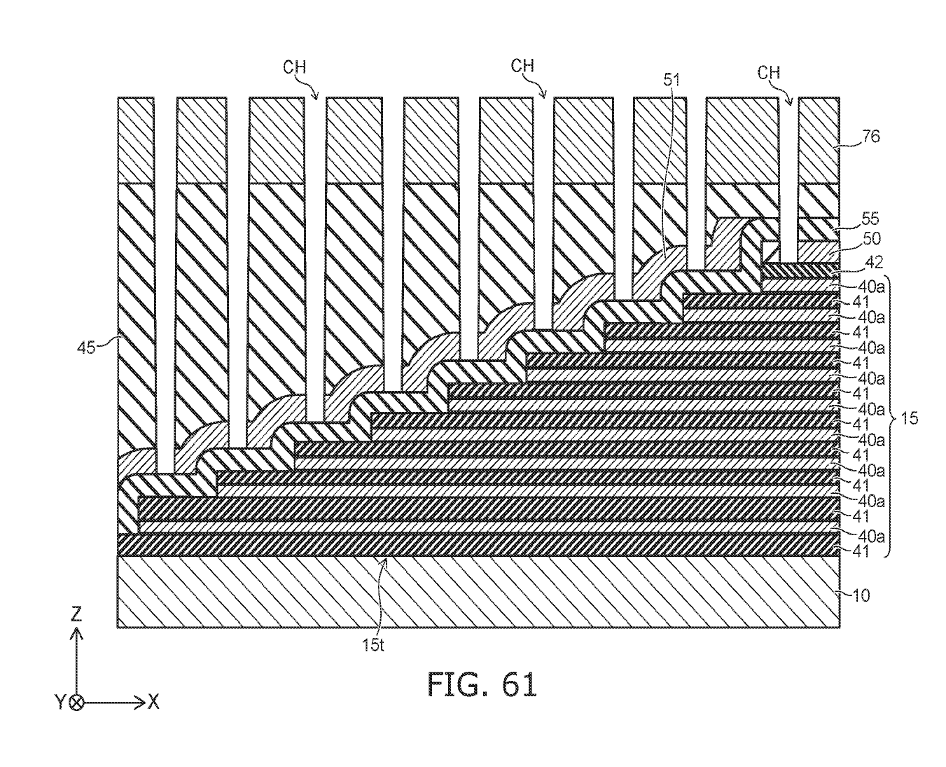

Then, as shown in FIG. 61, the conductive films 50, 51 located immediately below the contact holes CH are removed. It should be noted that a part of the insulating film 76 is removed together with the removal of the conductive films 50, 51.

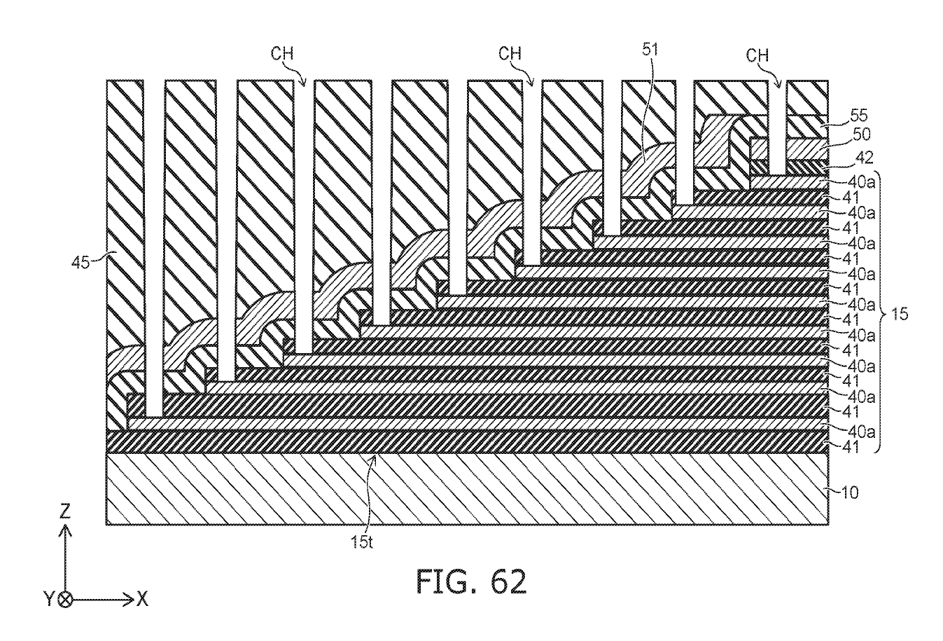

Then, as shown in FIG. 62, the insulating films 41, 42, 55 located immediately below the contact holes CH are removed. Thus, the contact holes CH reach the respective electrode films 40a. It should be noted that a part of the insulating film 76 is removed together with the removal of the insulating films 41, 42, 55.

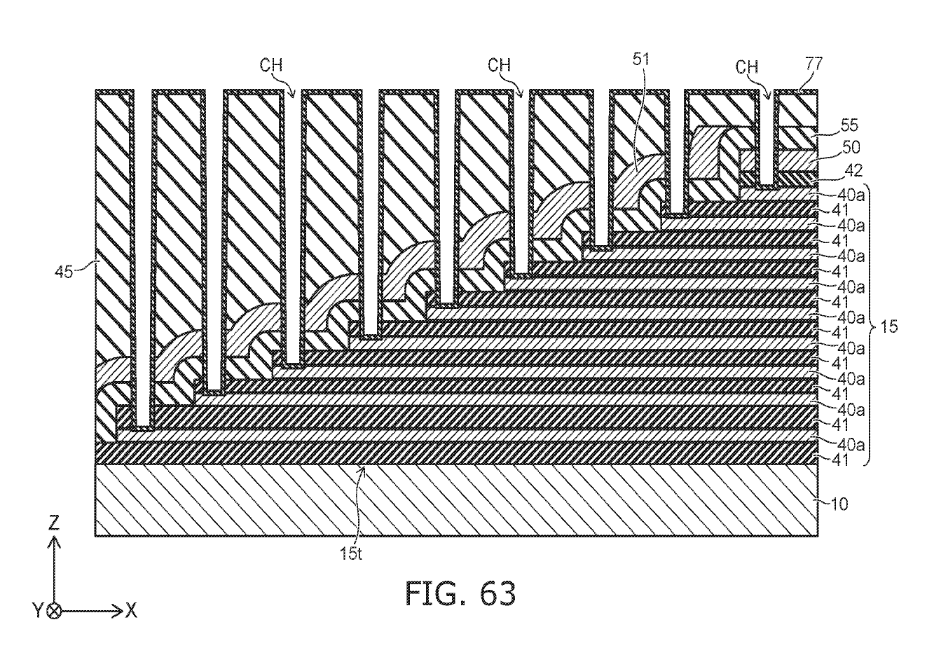

Then, as shown in FIG. 63, the insulating film 77 is formed on the insulating film 45, and the inside wall surface and the bottom surface of each of the contact holes CH.

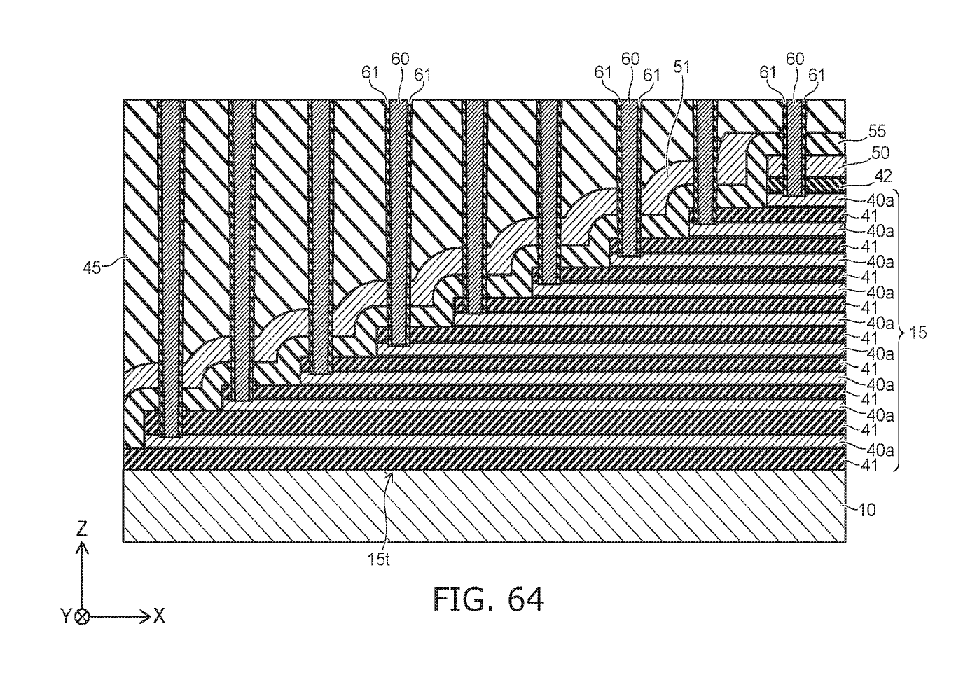

Then, as shown in FIG. 64, the upper surface of the insulating film 45 is removed to thereby remove the insulating film 77 on the insulating film 45 and remove the insulating film 77 on the bottom surface of each of the contact holes CH. By removing a part of the insulating film 77, the spacer 61 is formed. It should be noted that in the case in which the insulating films 80, 81 are formed instead of the conductive films 50, 51 in the process shown in FIG. 51 and FIG. 54, it is not necessary to form the spacer 61. Subsequently, the contact 60 is formed in each of the contact holes CH.

The semiconductor memory device 4 is manufactured in such a manner as described above.

The advantages of the embodiment are the same as the advantages of the first embodiment described above.

### Fifth Embodiment

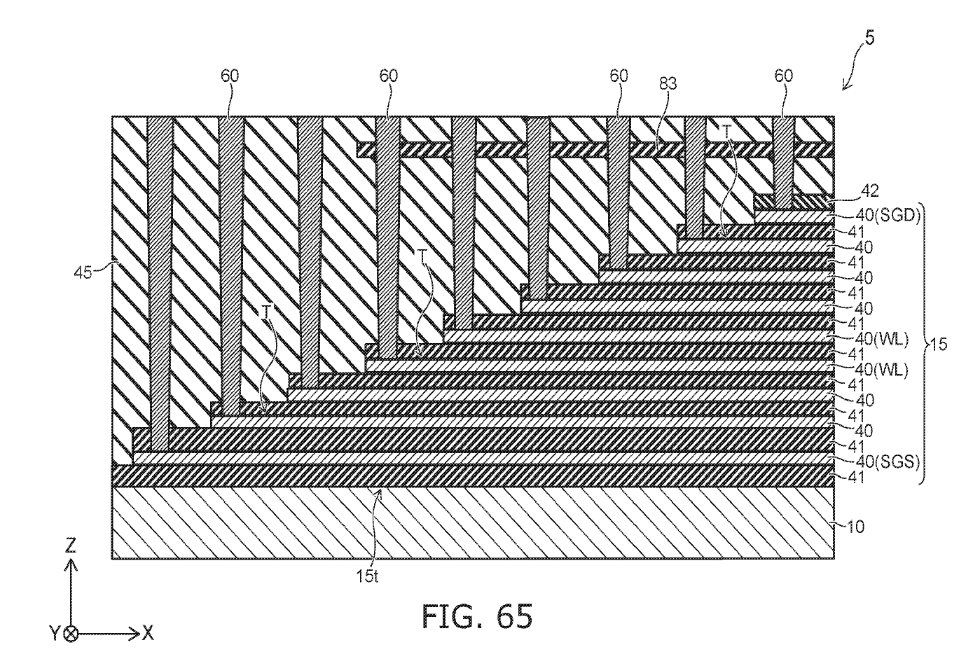

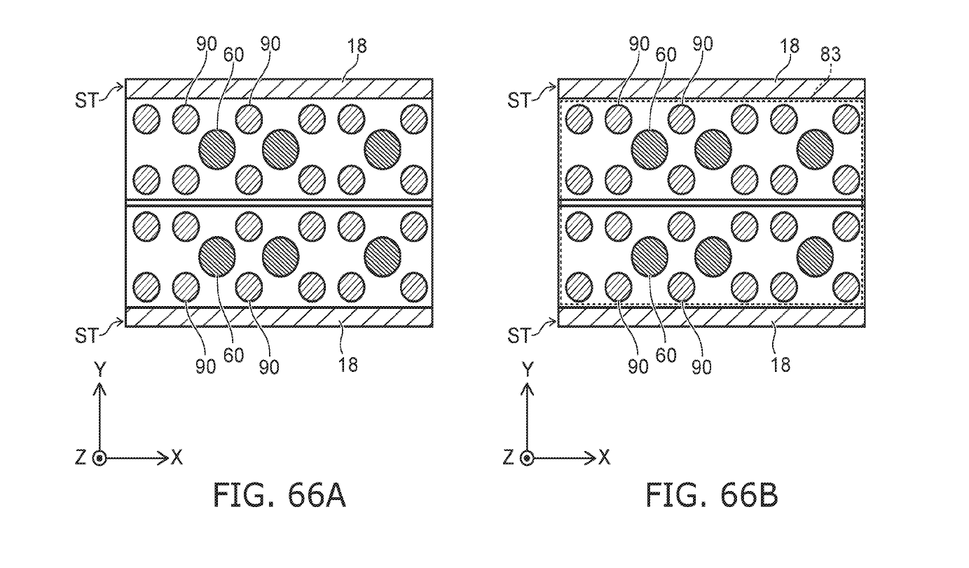

FIG. 65 is a cross-sectional view showing a semiconductor memory device 5. FIG. 66A and FIG. 66B are each a top view of the semiconductor memory device 5.

The area shown in FIG. 65 corresponds to the area showing the end part 15t of the stacked body 15 in FIG. 1. FIG. 66A and FIG. 66B show the upper surface of a part of the area shown in FIG. 65, and respectively show the upper surface on the lower-layer side and the upper surface on the upper-layer side of the stacked body 15.

As shown in FIG. 65, the semiconductor memory device 5 according to the embodiment is different in the point that the insulating film 83 is provided instead of the conductive part (the conductive films 50, 51) and the insulating film 55 compared to the semiconductor memory device 1 according to the first embodiment.

The semiconductor memory device 5 is provided with the insulating film 83, and the plurality of contacts 60. The insulating film 83 and the contacts 60 are provided on the end part 15t of the stacked body 15.

The insulating film 83 extends through the insulating film in the X-direction. The insulating film 83 includes a different material from that of the insulating film 45. The insulating film 83 includes, for example, silicon nitride.

As shown in FIG. 65 and FIG. 66A, the insulating film 83 does not overlap the terraces T of the three electrode films 40 on the lower-layer side when viewed from the Z-direction.

As shown in FIG. 65 and FIG. 66B, a part of the insulating film 83 overlaps the terraces T of the three electrode films 40 on the upper-layer side when viewed from the Z-direction.

As shown in FIG. 65, a part of the insulating film 83 overlaps the terraces T of the three intermediate electrode films 40 when viewed from the Z-direction.

The electrode films 40 on the lower-layer side correspond to a group of the electrode films 40 shorter in distance in the Z-direction from the substrate 10 compared to other groups when classifying the electrode films 40 of the stacked body 15 into three groups. The electrode films 40 on the upper-layer side correspond to a group of the electrode films 40 longer in distance in the Z-direction from the substrate 10 compared to other groups. The intermediate electrode films 40 correspond to a group of the electrode films 40 located between the electrode films 40 on the lower-layer side and the electrode films 40 on the upper-layer side.

The number of the electrode films 40 in each of the groups is arbitrary. The electrode films 40 on the lower-layer side, the intermediate electrode films 40, and the electrode films 40 on the upper-layer side can be the same in number, or can also be different in number from each other.

As indicated by the dotted lines in FIG. 66B, the insulating film 83 is located between the slits ST. When viewed from the Z-direction, at least a part of the insulating film 83 overlaps the contacts 60. Although the shape of the insulating film 83 is a rectangular shape when viewed from the Z-direction, the shape of the insulating film 83 is not limited to a rectangular shape.

The contacts 60 are respectively located on the terraces T of the electrode films 40, and extend in the Z-direction in the end part 15t of the stacked body 15. The contacts 60 located on the terraces T of the electrode films 40 on the lower-layer side penetrate the insulating film 45. The contacts 60 located on the terraces T of the electrode films 40 on the upper-layer side and the intermediate electrode films 40 penetrate the insulating films 45, 83.

On the periphery of each of the contacts 60, there is provided a plurality of support members 90 for supporting the stacked body 15.

Then, a method of manufacturing the semiconductor memory device according to the embodiment will be described.

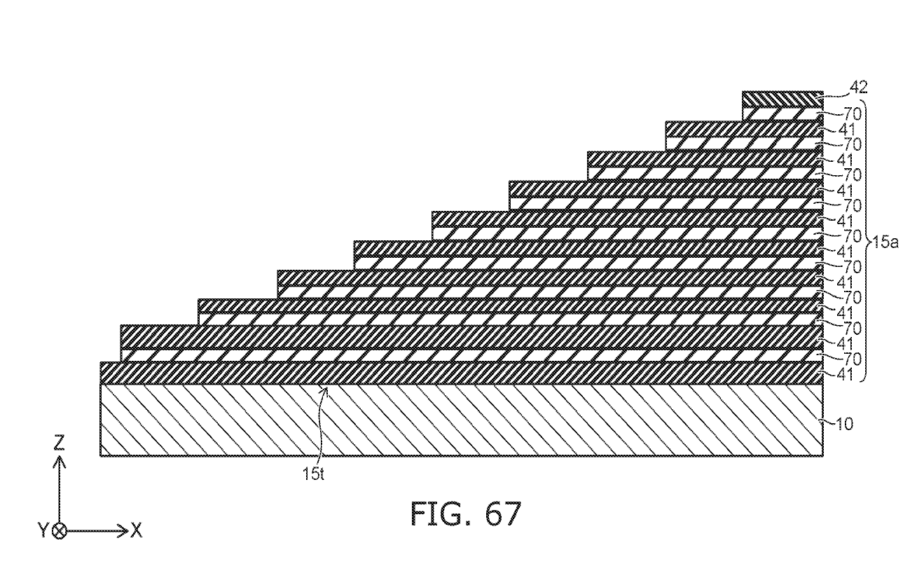

FIG. 67 through FIG. 72 are cross-sectional views showing the method of manufacturing the semiconductor memory device 5.

FIG. 67 through FIG. 72 each show the area corresponding to FIG. 65.

Firstly, as shown in FIG. 67, the insulating films 41 and the sacrificial films 70 are alternately stacked on one another along the Z-direction to form the stacked body 15a on the substrate 10. Subsequently, the insulating film 42 is formed on the stacked body 15a. Subsequently, the end part 15t of the stacked body 15a is processed to have a stepped shape.

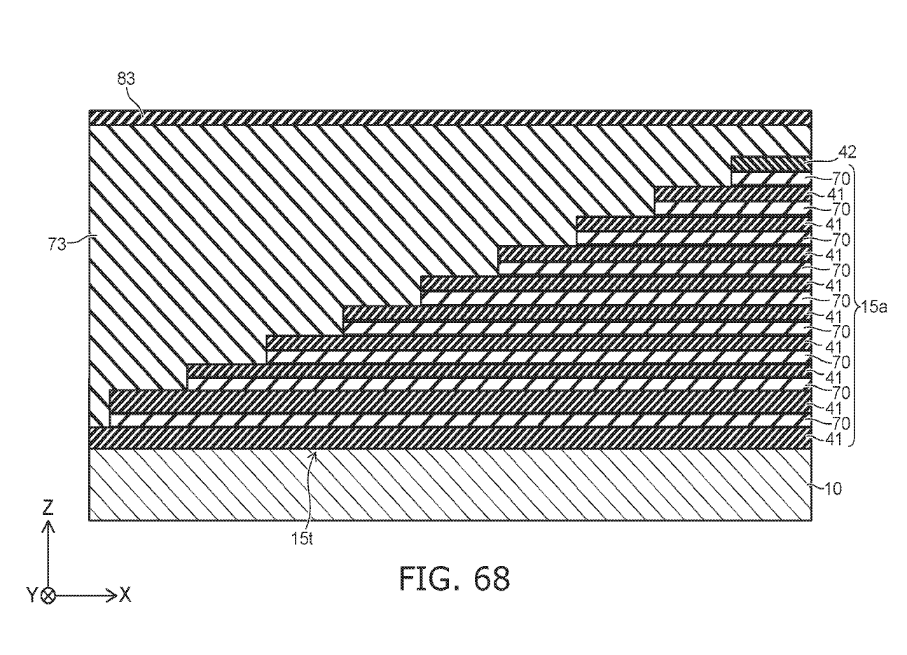

Then, as shown in FIG. 68, the insulating film 73 is formed so as to cover the end part 15t of the stacked body 15a. Subsequently, the insulating film 83 is formed on the insulating film 73. The insulating film 83 includes, for example, silicon nitride. For example, the thickness of the insulating film 83 is about 30 nanometers.

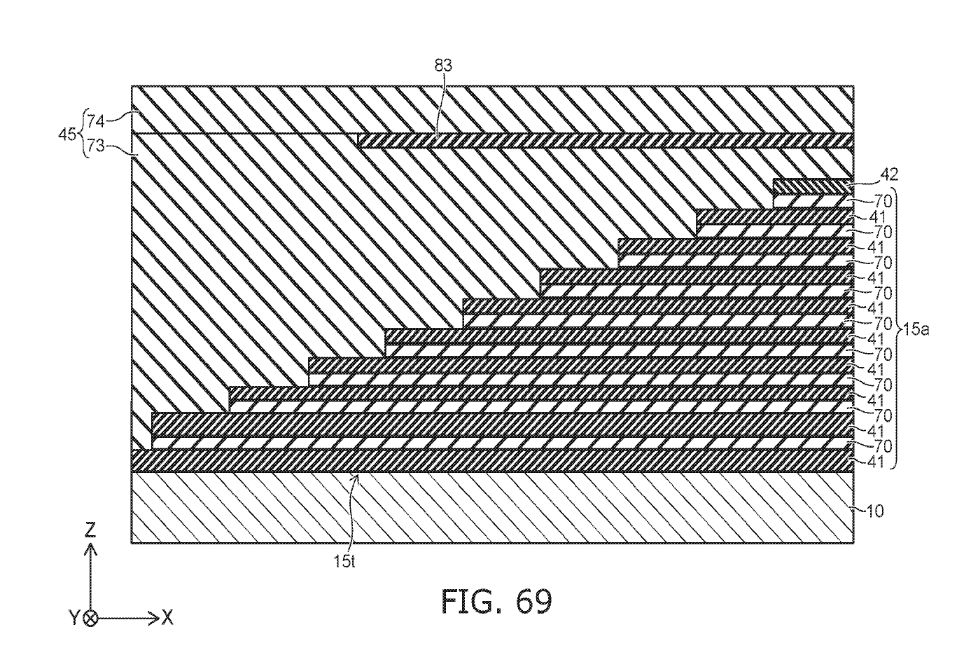

Then, as shown in FIG. 69, the insulating film 83 is patterned using a mask or the like. Thus, a part of the insulating film 83 is removed, and the insulating film 83 does not overlap a part of the end part 15t of the stacked body 15a when viewed from the Z-direction. Subsequently, the insulating film 74 is formed on the insulating film 73 and the insulating film 83. Thus, the insulating film 45 having the insulating film 73 and the insulating film 74 is formed. For example, the thickness of the insulating film 74 is about 365 nanometers.

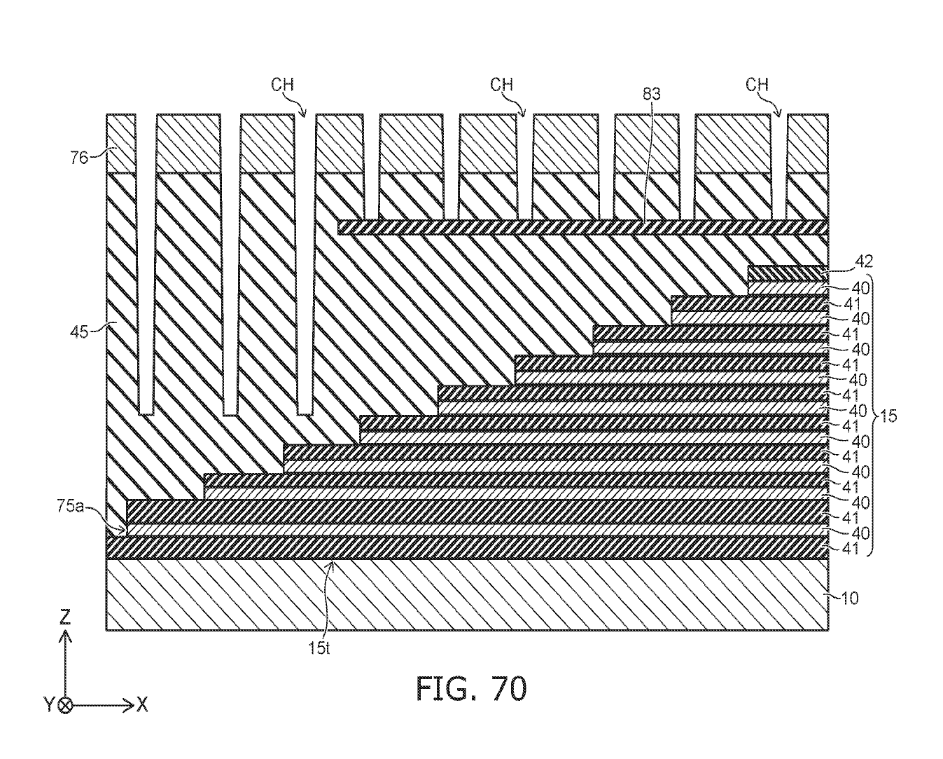

Then, as shown in FIG. 70, a plurality of slits ST extending in the X-direction and the Z-direction is provided to the stacked body 15a. Subsequently, wet-etching is performed via the slits ST to thereby remove the sacrificial films 70. Subsequently, metal is deposited via the slits ST to fill in the hollows 75a to form the electrode films 40. Thus, the stacked body 15 is formed between the slits ST. Subsequently, the interconnection part 18 is formed in each of the slits ST.

Subsequently, the insulating film 76 is formed on the insulating film 45, and then the contact holes CH are formed in the insulating films 45, 76.

The contact holes CH provided to the electrode films 40 on the upper-layer side and the intermediate electrode films 40 penetrate the insulating films 76, 45 and reach the insulating film 83. It is possible to stop etching without penetrating the insulating film 83 by the insulating film 76 thickly formed on the insulating film 45, and the etching selectivity between the insulating film 45 (e.g., a TEOS film) and the insulating film 83 (e.g., a silicon nitride film). In other words, the insulating film 83 functions as a film for stopping etching.

The contact holes CH provided to the electrode films 40 on the lower-layer side penetrate the insulating film 76. In the case of providing the contact holes CH to the electrode films 40 on the lower-layer side, there are set the etching conditions for vertically processing the insulating film 45 so that the bottom surface of each of the contact holes CH is located in the insulating film 45.

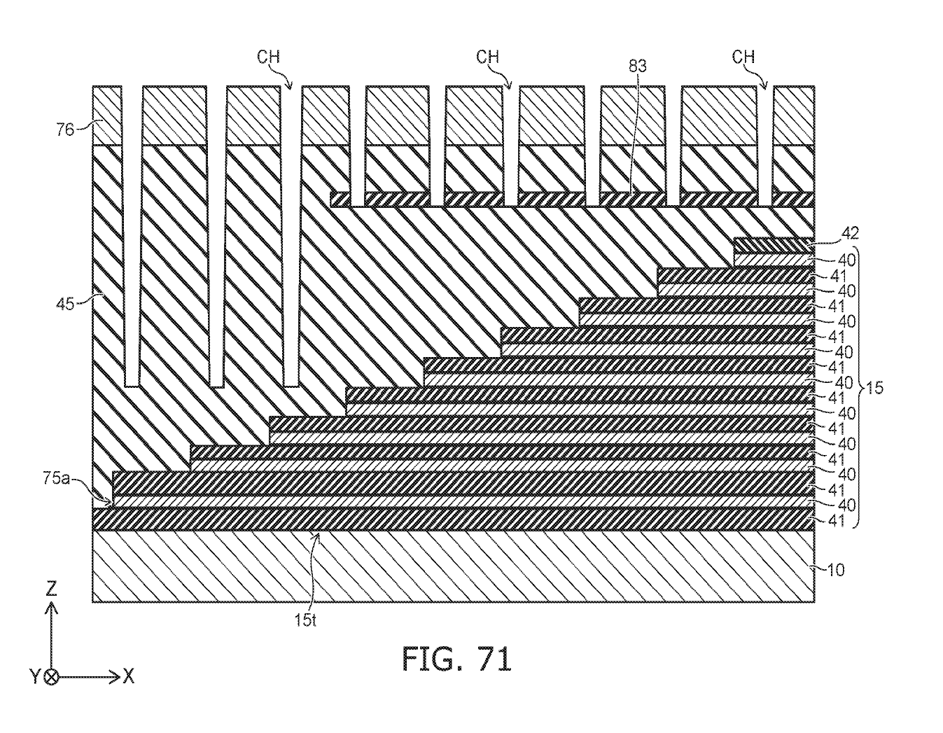

Then, as shown in FIG. 71, the insulating film 83, which is located immediately below the contact holes CH to be provided to the electrode films 40 on the upper-layer side and the intermediate electrode films 40, is removed. The contact holes CH reach the insulating film 45.

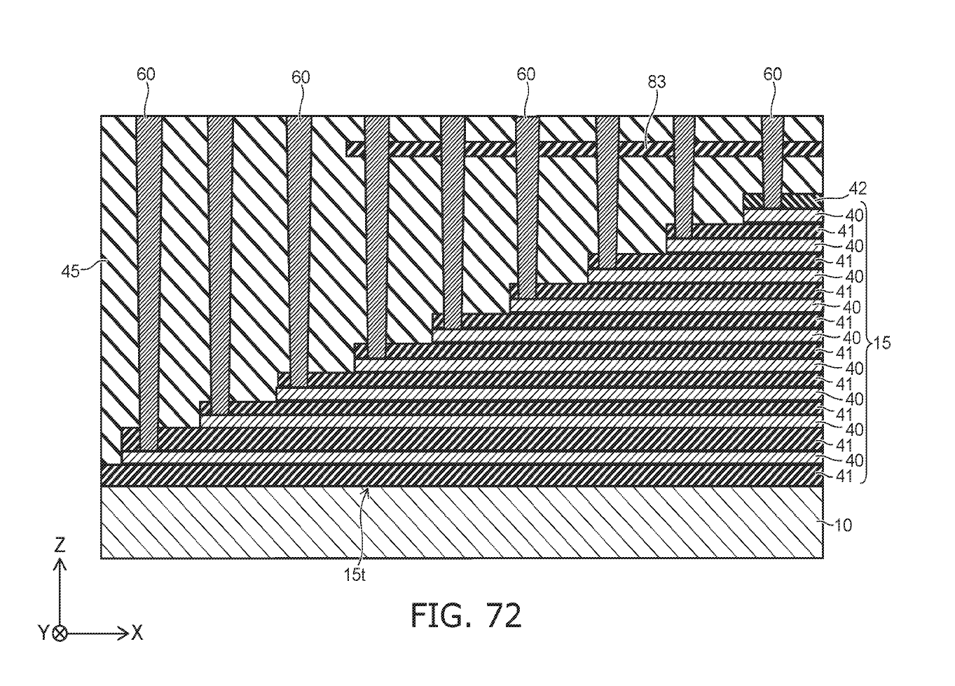

Then, as shown in FIG. 72, the insulating films 45, 41, 42 located immediately below the contact holes CH are removed. The contact holes CH reach the respective electrode films 40. The etching conditions between the insulating films 41, 42, 45 and the electrode films 40 are set so as not to penetrate the electrode films 40. It should be noted that the insulating film 76 is removed together with the removal of the insulating films 45, 41, 42. Subsequently, metal is deposited in each of the contact holes CH to form the contact 60.

The semiconductor memory device 5 is manufactured in such a manner as described above.

Then, advantages of the embodiment will be described.

In the embodiment, the semiconductor memory device 5 has the insulating film 83 provided in the insulating film 45 and on the end part 15t having the stepped shape of the stacked body 15. Such an insulating film 83 functions as a film for stopping etching as shown in FIG. 70. Thus, by stopping the etching in the contact holes CH to be provided to the electrode films 40 on the upper-layer side and the intermediate electrode films 40 in the insulating film 83, and then resuming the etching of the insulating films (the insulating films 41, 42, 45) with the etching conditions changed in all of the contact holes CH, it is possible to prevent the overetching of the contact holes CH provided to the electrode films 40 on the upper-layer side and the intermediate electrode films 40. Therefore, it is possible to prevent the short circuit between the electrode films 40, which occurs due to the penetration by the contact hole CH.

Further, in the embodiment, the contact holes CH are provided to the electrode films 40 on the lower-layer side by performing etching in a step-by-step manner with the etching conditions changed. Thus, it is possible to prevent the bottom surface of each of the contact holes CH to be provided to the electrode films 40 on the lower-layer side and the intermediate electrode films 40 from becoming smaller compared to the bottom surface of each of the contact holes CH to be provided to the electrode films 40 on the upper-layer side.

According to the embodiment described hereinabove, it is possible to provide the semiconductor memory device, which is easy to provide the contact to the part having the stepped shape of the stacked body, and is improved in reliability, and the method of manufacturing the semiconductor memory device.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions. Additionally, the embodiments described above can be combined mutually.

What is claimed is:

1. A semiconductor memory device comprising:
a substrate;
a stacked body provided on the substrate, and including a plurality of electrode films extending in a first direction along an upper surface of the substrate and stacked with spacing from each other, an end part of the stacked body having a stepped shape provided with a terrace for each of the electrode films;
a first insulating film provided on the end part of the stacked body; and
a first film provided on the first insulating film, and extending in a direction tilted with respect to the first direction.

2. The device according to claim 1, further comprising:
a contact located on the terrace of the electrode film, and extending through the first insulating film and the first film in a stacking direction of the plurality of electrode films; and
a second insulating film provided on a periphery of the contact,
wherein the first film has a conductive property.

3. The device according to claim 1, wherein
the first film includes a same material as a material that the plurality of electrode films is formed.

4. The device according to claim 1, wherein
the first film includes at least one of tungsten, molybdenum, and polysilicon.

5. The device according to claim 1, wherein
the first film has a conductive property, and
the first film has a first part overlapping the terrace of the electrode film of an uppermost layer when viewed from a stacking direction of the plurality of electrode films, and a second part spaced from the first part and overlapping the terraces of the electrode films other than the electrode film of the uppermost layer.

6. The device according to claim 5, wherein
the first insulating film is located between the first part and the second part of the first film in the first direction.

7. The device according to claim 1, further comprising:
a contact located on the terrace of the electrode film, and extending through the first insulating film and the first film in a stacking direction of the plurality of electrode films,
wherein the first film has an insulating property.

8. The device according to claim 7, wherein
the first film includes at least one of silicon nitride, aluminum oxide, hafnium oxide, and titanium oxide.

9. The device according to claim 7, wherein
the first film has an insulating property, and
the first film has a first part overlapping the terrace of the electrode film of an uppermost layer when viewed from the stacking direction of the plurality of electrode films, and a second part spaced from the first part and overlapping the terraces of the electrode films other than the electrode film of the uppermost layer.

10. The device according to claim 7, wherein
the first film has an insulating property,
the first film is not overlapped with the terrace of the electrode film of the uppermost layer when viewed from the stacking direction of the plurality of electrode films, and
the contact is not located on the terrace of the electrode film of the uppermost layer.

11. The device according to claim 1, wherein
the plurality of electrode films includes polysilicon.

12. The device according to claim 1, wherein
a material of the first film is different from a material of the first insulating film.

13. The device according to claim 1, further comprising:
a plurality of interconnection parts provided in the stacked body, and disposed in a second direction crossing the first direction, each of the interconnection parts extending in the first direction to an end part of the stacked body,
wherein the first insulating film and the first film are located between the interconnection parts.

14. A semiconductor memory device comprising:
a substrate;
a stacked body provided on the substrate, and including a plurality of electrode films extending in a first direction along an upper surface of the substrate and stacked with spacing from each other, an end part of the stacked body having a stepped shape provided with a terrace for each of the electrode films;
a first insulating film provided on the end part of the stacked body; and
a second insulating film provided on the first insulating film, and including a different material from a material of the first insulating film, the second insulating film being not overlapped with some of the plurality of electrode films when viewed from a stacking direction of the plurality of electrode films.

15. The device according to claim 14, wherein
the plurality of electrode films is divided into a plurality of groups from an upper-layer side to a lower-layer side of the stacked body, and
the second insulating film is not overlapped with the electrode film located on the lower-layer side of the stacked body when viewed from the stacking direction.

16. The device according to claim 14, wherein
the plurality of electrode films is divided into three groups from an upper-layer side to a lower-layer side of the stacked body, and
the second insulating film overlaps, when viewed from the stacking direction, the electrode film located on the upper-layer side of the stacked body, and the electrode film between the electrode film located on the upper-layer side of the stacked body and the electrode film located on the lower-layer side of the stacked body.

17. The device according to claim 14, further comprising:
a contact located on the terrace of the electrode film, and extending in the stacking direction,
wherein the contact has a first contact located on the terrace of the electrode film overlapping the second insulating film when viewed from the stacking direction, and
the first contact penetrates the second insulating film.

18. The device according to claim 14, wherein
the second insulating film includes silicon nitride.

19. A method for manufacturing a semiconductor memory device, comprising:
forming a stacked body on a substrate by alternately stacking a first insulating film and a first film extending in a first direction along an upper surface of the substrate;
forming a second insulating film on the stacked body;
forming a second film on the second insulating film;
providing an end part of the stacked body with a stepped shape by etching the stacked body, the second insulating film and the second film;
forming a third insulating film on the end part of the stacked body;
forming a third film on the third insulating film;
forming a slit extending in the first direction and a stacking direction of the stacked body so as to penetrate the stacked body, the second insulating film, the second film, the third insulating film, and the third film;
removing the first film, the second film, and the third film to form hollows, and forming a first conductive film, a second conductive film and a third conductive film in the hollows, respectively, via the slit;
forming a through hole penetrating the first insulating film, the second insulating film, the third insulating film, the second conductive film and the third conductive film on a terrace of the first conductive film in the end part of the stacked body;
forming a fourth insulating film on an inside wall surface of the through hole; and
forming a fourth conductive film on the fourth insulating film in the through hole.

20. The method according to claim 19, wherein
the forming the through hole includes penetrating the second conductive film and the third conductive film, and penetrating the first insulating film, the second insulating film and the third insulating film.
